(19) United States
(12) Patent Application Publication
(10) Pub. No.: US 2026/0220509 A1
(43) Pub. Date: Jul. 30, 2026

(54) QUBIT ARRAY, QUANTUM COMPUTER, AND QUANTUM INFORMATION PROCESSING METHOD

(71) Applicant: Hitachi, Ltd., Tokyo (JP)

(72) Inventors: Saki SUSA, Tokyo (JP); Tatsuya TOMARU, Tokyo (JP)

(21) Appl. No.: 19/146,390

(22) PCT Filed: Apr. 27, 2023
(86) PCT No.: PCT/JP2023/016711

§ 371 Date: Jul. 8, 2025

(51) Int. Cl. G06N 10/20; G06N 10/40; G06N 10/60; H10N 60/10; H10N 69/00

(52) U.S. Cl. CPC G06N 10/20; G06N 10/40; G06N 10/60; H10N 60/128; H10N 69/00

(57) ABSTRACT

To enable further large-scale integration of a qubit array, a qubit array having at least two quantum dot lines extending in a first direction is provided. The array includes a single qubit gate section performing a single qubit gate operation, an entanglement state generation section that includes a longitudinal two qubit gate section for performing a two qubit gate operation in the first direction for the quantum bits and a lateral two qubit gate section for performing a two qubit gate operation in a second direction for quantum bits, an XY single qubit gate section for performing a rotation operation around a preset arbitrary axis for the plurality of quantum bits according to a program given from outside, a Z measurement section for performing a measurement operation for the plurality of quantum bits, and a control section for performing a shuttling operation for the quantum bits in the first direction.

### TECHNICAL FIELD

The present invention relates to techniques of a quantum information processor and a quantum information processing method.

### BACKGROUND ART

A large number of quantum bits are necessary to realize a fault tolerant quantum computer. In order to control quantum bits, antenna lines for applying microwaves and voltage control lines for changing a gate voltage/barrier potential are necessary. If a control line is designed to be arranged for each of all quantum bits, the number of control lines increases in proportion to the number of quantum bits. Accordingly, when the number of quantum bits is increased, an increased number of control lines occupy the chip area. In order to solve the problem of scalability due to the increased number of control lines, a common wiring structure in which a single control line simultaneously controls a plurality of quantum bits as described in Patent Document 1 is suitable.

In such a device disclosed in Patent Document 1, quantum bits are arranged in an array, and common control lines are provided on a column or row basis. By causing a plurality of control lines to operate in combination, it is possible to perform a single qubit gate operation for each quantum bit. In addition, a two qubit gate operation is applied to quantum bit pairs in the same column or in the same row. These operations enable universal quantum computation.

In a quantum dot array disclosed in Patent Document 1, for example, barrier potential voltage control lines that apply a voltage in the vertical direction are wired at equal intervals just above nano-sized semiconductor thin lines. In addition, gate voltage control lines that induce electrons are arranged between the barrier potential voltage control lines. The voltage applied to the barrier potential control lines generates a voltage potential inside the semiconductor thin lines. The region sandwiched between the barrier potentials functions as a quantum dot. Since the nanoscale semiconductor thin lines are provided, the energy in the potential is quantized, and quantum dots are formed. By applying a voltage to the gate voltage control lines, electrons inside the semiconductor thin lines are induced, and the electrons can be confined in the quantum dots. The number of electrons to be confined is determined according to the magnitudes of the gate voltage and the barrier voltage.

A measurement operation in quantum systems causes a quantum state transfer. In particular, by appropriately measuring a strongly entangled quantum state such as a Bell state, quantum teleportation in which quantum information that cannot be copied in principle is moved from a specific quantum bit to another quantum bit becomes possible. At this time, the quantum state changes between before and after the teleportation according to the measurement result and a physical quantity to be measured. By quantum computation of this change, measurement-based quantum computation (MBQC) is implemented (Non Patent Document 1).

In the MBQC, a method of quantum computation by measuring an entangled cluster state in one direction is called one way quantum computation (Non Patent Document 2).

### PRIOR ART DOCUMENTS

### Patent Document

Patent Document 1: JP-2021-027142-A

### Non Patent Documents

Non Patent Document 1: R. Raussendorf, D. E. Browne, and H. J. Briegel, “Measurement-based quantum computation on cluster states,” Phys. Rev. A, vol. 68, 022312 (2003)
Non Patent Document 2: R. Raussendorf and H. J. Briegel, “A One-Way Quantum Computer,” Phys. Rev. Lett., vol. 86, 5188 (2001)
Non Patent Document 3: F Ginzel, A. R. Mills, J. R. Petta, and G. Burkard, “Spin shuttling in a silicon double quantum dot,” Phys. Rev. B, vol. 102, 195418 (2020)

### SUMMARY OF THE INVENTION

### Problem to be Solved by the Invention

FIG. 1 depicts a schematic diagram of physical quantum bits. It is assumed that the number of logical qubits required for quantum computation processing to be executed is L. For example, the one way quantum computation is implemented by using quantum bits such as physical quantum bits (100) arranged in a lattice shape of L×2 as depicted in FIG. 1. According to Patent Document 1 and the like, such a quantum dot array can be configured by a semiconductor circuit technology.

FIG. 2A is a schematic diagram for depicting a procedure for one way quantum computation with physical quantum bits. The method of the one way quantum computation is represented by a conceptual diagram in FIG. 2A. FIG. 2A depicts a cluster state that is the initial state necessary to perform the one way quantum computation and the order of measurement of the cluster state. The order of operation and measurement is indicated by the direction of an arrow (300).

In FIG. 2A, circles indicate physical quantum bits (100), and a thick line connecting the circles indicates entanglement (200). The physical quantum bits (100) arranged in a lattice shape are entangled with adjacent quantum bits, that is, they are in a quantum state called a cluster state. The quantum computation is implemented by measuring the cluster state for each column from the leftmost column (02001).

That is, desired quantum computation is implemented by advancing the measurement from the column (02001) towards a column (02002), a column (02003), a column (02004), . . . , in this order by a basis B(φj).

The cluster state is a quantum state obtained by performing a CZ gate operation between adjacent ones of physical quantum bits initialized to a o|+> state (where o is substituted for a tensor product symbol with X written in a circle). The CZ gate operation inverts the phase of a target bit when a control gate is 1.

Note that the |+> state is given by a tensor product of a vector |+> of (Equation 1).

$$[ Math . 1 ]$$

$$\vert + 〉 = \frac{1}{\sqrt{2}} [ \begin{matrix}1 \\ 1\end{matrix} ] \qquad ( Equation 1 )$$

Note that the CZ gate is given by the matrix of (Equation 2).

$$[ Math . 2 ]$$

$$[ \begin{matrix}1 & 0 & 0 & 0 \\ 0 & 1 & 0 & 0 \\ 0 & 0 & 1 & 0 \\ 0 & 0 & 0 & - 1\end{matrix} ] \qquad ( Equation 2 )$$

Note that a measurement basis B(φⱼ) necessary for the quantum operation is given by (Equation 3).

$$[ Math . 3 ]$$

$$ℬ ( {ϕ}_{j} ) = \{ \frac{\vert 0 〉 + {e}^{i {ϕ}_{j}} \vert 1 〉}{\sqrt{2}} , \frac{\vert 0 〉 - {e}^{i {ϕ}_{j}} \vert 1 〉}{\sqrt{2}} \} \qquad ( Equation 3 )$$

Here, B(φⱼ) satisfies (Equation 4).

$$\begin{matrix}[ Math . 4 ] & \\ \begin{matrix}B ( {ϕ}_{j} ) = \{ \frac{\vert 0 〉 + {e}^{i {ϕ}_{j}} \vert 1 〉}{\sqrt{2}} , \frac{\vert 0 〉 - {e}^{i {ϕ}_{j}} \vert 1 〉}{\sqrt{2}} \} \\ = \{ {U}_{M} ( {ϕ}_{j} ) \vert 0 〉 , {U}_{M} ( {ϕ}_{j} ) \vert 1 〉 \}\end{matrix} & ( Equation 4 )\end{matrix}$$

Therefore, the measurement by the basis B(φⱼ) is implemented by U_{M}(φⱼ) satisfying (Equation 5) and Z measurement.

$$\begin{matrix}[ Math . 5 ] & \\ \begin{matrix}{U}_{M} ( {ϕ}_{j} ) = \frac{1}{\sqrt{2}} [ \begin{matrix}1 & {e}^{i {ϕ}_{j}} \\ 1 & - {e}^{i {ϕ}_{j}}\end{matrix} ] \\ = {e}^{i {ϕ}_{j} / 2} \frac{1}{\sqrt{2}} [ \begin{matrix}1 & 1 \\ 1 & - 1\end{matrix} ] [ \begin{matrix}{e}^{- i {ϕ}_{j} / 2} & 0 \\ 0 & {e}^{i {ϕ}_{j} / 2}\end{matrix} ] \\ = {e}^{i {ϕ}_{j} / 2} {HR}_{z} ( - {ϕ}_{j} )\end{matrix} & ( Equation 5 )\end{matrix}$$

Note that an H gate is given by the matrix of (Equation 6).

$$\begin{matrix}[ Math . 6 ] & \\ \frac{1}{\sqrt{2}} [ \begin{matrix}1 & 1 \\ 1 & - 1\end{matrix} ] & ( Equation 6 )\end{matrix}$$

Note that an Rz(θ) gate is given by the matrix of (Equation 7).

$$\begin{matrix}[ Math . 7 ] & \\ [ \begin{matrix}{e}^{- i {ϕ}_{j} / 2} & 0 \\ 0 & {e}^{i {ϕ}_{j} / 2}\end{matrix} ] & [ Equation 7 )\end{matrix}$$

FIG. 2B to FIG. 2F depict individual quantum operations by embodying the conceptual diagram of FIG. 2A. The measurement for a computation operation is performed by the measurement basis B(φⱼ) of (Equation 5). In each diagram, a parameter on the left side of the equal sign indicates the value of a rotation angle for determining the measurement basis, and a logical qubit circuit model is depicted on the right side of the equal sign. In FIG. 2B to FIG. 2F, each circle represents a quantum bit, and a numeral in the circle indicates the value of the parameter φⱼ of the measurement basis.

FIG. 2B depicts a CNOT gate, FIG. 2C depicts a general single qubit rotation Uᵣₒₜ gate, FIG. 2D depicts a n rotation Rz(η) gate in the Z axis, FIG. 2E depicts an H gate, and FIG. 2F depicts a flow of measurement necessary for implementing an S gate.

Note that the CNOT gate is given by the matrix of (Equation 8).

$$\begin{matrix}[ Math . 8 ] & \\ [ \begin{matrix}1 & 0 & 0 & 0 \\ 0 & 1 & 0 & 0 \\ 0 & 0 & 0 & 1 \\ 0 & 0 & 1 & 0\end{matrix} ] & ( Equation 8 )\end{matrix}$$

Note that the single qubit Uᵣₒₜ gate for logical qubits is given by the matrix of (Equation 9).

$$\begin{matrix}[ Math . 9 ] & \\ [ \begin{matrix}cos ( ς / 2 ) & - i sin ( ς / 2 ) \\ - i sin ( ς / 2 ) & cos ( ς / 2 )\end{matrix} ] [ \begin{matrix}{e}^{- i η / 2} & 0 \\ 0 & {e}^{i η / 2}\end{matrix} ] \\ [ \text{} \begin{matrix}cos ( ξ / 2 ) & - i sin ( ξ / 2 ) \\ - i sin ( ξ / 2 ) & cos ( ξ / 2 )\end{matrix} ] & ( Equation 9 )\end{matrix}$$

Note that the R_{z}(η) gate for logical qubits is given by the matrix of (Equation 10).

$$\begin{matrix}[ Math . 10 ] & \\ [ \begin{matrix}{e}^{- i η / 2} & 0 \\ 0 & {e}^{i η / 2}\end{matrix} ] & ( Equation 10 )\end{matrix}$$

Note that the S gate is given by the matrix of (Equation 11).

$$\begin{matrix}[ Math . 11 ] & \\ [ \begin{matrix}1 & 0 \\ 0 & i\end{matrix} ] & ( Equation 11 )\end{matrix}$$

FIG. 3 depicts a processing method for executing the measurement operation of FIG. 2A with the device of FIG. 1. Physical quantum bits arranged in L columns and two rows are initialized to the o|0> state, an operation of the H gate is performed for the quantum bits to form the o|+> state (S03001), and the quantum bits are entangled by the CZ gate to generate a cluster state (A) (S03002). Thereafter, measurement is performed for quantum bits (01001) in the first row by the basis B(φⱼ) corresponding to a state (02001) (S03003).

Then, the entanglement between the quantum bits (01001) in the first row is completely lost. At this time, quantum information in the quantum bits (01001) in the first row is moved to quantum bits (01002) in the second row together with the measurement basis B(φⱼ) and an information change according to the measurement result, and the quantum state of the quantum bits (01002) in the second row is changed (B).

The quantum bits (01001) in the first row are initialized to o|0> again, and entangled with the quantum bits (01002) in the second row by the H gate and the CZ gate again to generate a cluster state (C) (S03004). Thereafter, measurement is performed for the quantum bits (01002) in the second row by the basis B(φⱼ) corresponding to the state (02002), causing a quantum state transfer (D) (S03005).

Further, the quantum bits (01002) in the second row are initialized to o|0> again, and entangled with the quantum bits (01001) in the first row by the H gate and the CZ gate again to generate a cluster state (E) (S03006). Measurement is performed for the quantum bits (01001) in the first row by the basis B(φⱼ) corresponding to the state (02003). In this way, the cluster state generation and the measurement operation by the basis B(φⱼ) are repeated, thereby implementing a desired quantum operation.

Next, hardware generated in large-scale integration will be considered. In order to implement quantum computation, at least three kinds of operations, i.e., a single qubit gate operation, a two qubit gate operation, and quantum measurement, are necessary. Here, a quantum bit element present in the device is called a physical quantum bit, and the unit of quantum information is called a logical qubit. In the case where there is no need to distinguish them from each other, they are simply called quantum bits in some cases.

In the case where physical quantum bits and logical qubits are associated on a one-to-one basis to perform quantum computation processing, a mechanism for implementing a plurality of kinds of operations for all the physical quantum bits is necessary. That is, it is necessary to make physical quantum bits multifunctional. This multifunctionality can lead to a problem of an increase in the density of control wirings and a decrease in operation accuracy due to an error such as crosstalk, for example. In particular, a measurement operation requires a function of transferring measurement results as classical information to the outside of the quantum bit device, and thus requires a larger circuit area in the quantum device than other quantum operations. Therefore, if all the physical quantum bits are made multifunctional, peripheral circuits for operations become larger than physical quantum bit elements, and large-scale integration becomes difficult.

Therefore, an object of the present invention is to enable further large-scale integration of a qubit array.

### Means for Solving the Problem

According to a preferred aspect of the present invention, there is provided a qubit array having at least two quantum dot lines extending in a first direction, the array including a single qubit gate section for performing a single qubit gate operation for a plurality of quantum bits on the quantum dot lines, an entanglement state generation section that includes a longitudinal two qubit gate section for performing a two qubit gate operation in the first direction for the plurality of quantum bits and a lateral two qubit gate section for performing a two qubit gate operation in a second direction for the plurality of quantum bits, the second direction being different from the first direction, an XY single qubit gate section for performing a rotation operation around a preset arbitrary axis for the plurality of quantum bits according to a program given from outside, a Z measurement section for performing a measurement operation for the plurality of quantum bits, and a control section for performing a shuttling operation for the plurality of quantum bits in the first direction.

According to another preferred aspect of the present invention, there is provided a quantum computer including an input unit, an output unit, a storage unit, a processing unit, and a quantum operation unit using the above-described qubit array, in which the input unit receives a quantum algorithm, and the processing unit generates a control command for controlling the qubit array according to the quantum algorithm.

According to still another preferred aspect of the present invention, there is provided a quantum information processing method performed by a qubit array having at least two quantum dot lines extending in a first direction. The qubit array includes a single qubit gate section for performing a single qubit gate operation for a plurality of quantum bits on the quantum dot lines, an entanglement state generation section that includes a longitudinal two qubit gate section for performing a two qubit gate operation in the first direction for the plurality of quantum bits and a lateral two qubit gate section for performing a two qubit gate operation in a second direction for the plurality of quantum bits, the second direction being different from the first direction, an XY single qubit gate section for performing a rotation operation around a preset arbitrary axis for the plurality of quantum bits according to a program given from outside, a Z measurement section for performing a measurement operation for the plurality of quantum bits, and a control section for moving the plurality of quantum bits in the first direction. The method includes a first step of performing a single qubit gate operation for a first quantum bit and a second quantum bit in the single qubit gate section, a second step of moving the first quantum bit and the second quantum bit to the entanglement state generation section by the control section, a third step of entangling the first quantum bit and the second quantum bit in the entanglement state generation section, a fourth step of moving the first quantum bit and the second quantum bit to the XY single qubit gate section by the control section, a fifth step of performing the rotation operation for at least one of the first quantum bit and the second quantum bit in the XY single qubit gate section, a sixth step of moving the first quantum bit and the second quantum bit to the Z measurement section by the control section, and a seventh step of performing the measurement operation for at least one of the first quantum bit and the second quantum bit in the Z measurement section.

### Advantages of the Invention

It is possible to realize further large-scale integration of a qubit array.

### BRIEF DESCRIPTION OF THE DRAWINGS

FIG. 1 is a conceptual diagram of a device used for one way quantum computation processing.

FIG. 2A is a conceptual diagram for depicting a general operation method of the one way quantum computation processing.

FIG. 2B is a conceptual diagram for depicting a concrete operation method of the one way quantum computation processing (CNOT).

FIG. 2C is a conceptual diagram for depicting a concrete operation method of the one way quantum computation processing (general single qubit rotation gate).

FIG. 2D is a conceptual diagram for depicting a concrete operation method of the one way quantum computation processing (Z-axis rotation gate).

FIG. 2E is a conceptual diagram for depicting a concrete operation method of the one way quantum computation processing (H gate).

FIG. 2F is a conceptual diagram for depicting a concrete operation method of the one way quantum computation processing (S gate).

FIG. 3 is a conceptual diagram of a quantum circuit operation necessary for the one way quantum computation processing and necessary for performing the processing of FIG. 2A to FIG. 2F using the device of FIG. 1.

FIG. 4 is a schematic diagram of a device according to an embodiment in which the one way quantum computation is implemented by shuttling.

FIG. 5 is a schematic diagram for depicting a flow of processing for implementing the one way quantum computation by shuttling proposed in the embodiment, in which the processing necessary for the one way quantum computation is summarized.

FIG. 6 is a quantum circuit diagram for depicting a device operation for implementing the one way quantum computation by shuttling proposed in the embodiment.

FIG. 7A is an explanatory diagram in which a state of the device for implementing the one way quantum computation by shuttling proposed in the embodiment in each time step is depicted on the left side and executed quantum operations are depicted on the right side (time step 1).

FIG. 7B is an explanatory diagram in which a state of the device for implementing the one way quantum computation by shuttling proposed in the embodiment in each time step is depicted on the left side and executed quantum operations are depicted on the right side (time step 2).

FIG. 7C is an explanatory diagram in which a state of the device for implementing the one way quantum computation by shuttling proposed in the embodiment in each time step is depicted on the left side and executed quantum operations are depicted on the right side (time step 3).

FIG. 7D is an explanatory diagram in which a state of the device for implementing the one way quantum computation by shuttling proposed in the embodiment in each time step is depicted on the left side and executed quantum operations are depicted on the right side (time step 4).

FIG. 7E is an explanatory diagram in which a state of the device for implementing the one way quantum computation by shuttling proposed in the embodiment in each time step is depicted on the left side and executed quantum operations are depicted on the right side (time step 5).

FIG. 7F is an explanatory diagram in which a state of the device for implementing the one way quantum computation by shuttling proposed in the embodiment in each time step is depicted on the left side and executed quantum operations are depicted on the right side (time step 6).

FIG. 7G is an explanatory diagram in which a state of the device for implementing the one way quantum computation by shuttling proposed in the embodiment in each time step is depicted on the left side and executed quantum operations are depicted on the right side (time step 7).

FIG. 7H is an explanatory diagram in which a state of the device for implementing the one way quantum computation by shuttling proposed in the embodiment in each time step is depicted on the left side and executed quantum operations are depicted on the right side (time step 8).

FIG. 8 is a block diagram for depicting an outline of a quantum computation system.

FIG. 9 depicts the quantum computation system for implementing the one way quantum computation by shuttling proposed in the embodiment, and a flow of processing in the system.

FIG. 10A is a schematic diagram for depicting a device structure of a |+> state generation section (04110).

FIG. 10B is a quantum circuit diagram for depicting an example of the |+> state generation section (04110) (conversion from |0> to |+> by the H gate).

FIG. 10C is a quantum circuit diagram for depicting an example of the |+> state generation section (04110) (conversion from |0> to |+> by an Ry(π/2) gate).

FIG. 11A is a schematic diagram of a device structure of an entanglement generation section (04120) (longitudinal→lateral coupling).

FIG. 11B is a schematic diagram of a device structure of the entanglement generation section (04120) (lateral→longitudinal coupling).

FIG. 11C is a schematic diagram of a device structure of the entanglement generation section (04120) (longitudinal & lateral coupling).

FIG. 11D is a schematic diagram of a device structure of the entanglement generation section (04120) (lateral & longitudinal coupling).

FIG. 12A is a schematic diagram of a CZ gate and an equivalent circuit thereof (CZ gate).

FIG. 12B is a schematic diagram of a CZ gate and an equivalent circuit thereof (CZ gate using a CROT and a single qubit gate).

FIG. 12C is a schematic diagram of a CZ gate and an equivalent circuit thereof (CZ gate using a VSWAP and a single qubit gate).

FIG. 13A is a schematic diagram of a concrete configuration method of a longitudinal two qubit gate section (04122) (in the case where the CZ gate is a basic two qubit gate).

FIG. 13B is a schematic diagram of a concrete configuration method of the longitudinal two qubit gate section (04122) (in the case where the CROT is a basic two qubit gate).

FIG. 13C is a schematic diagram of a concrete configuration method of the longitudinal two qubit gate section (04122) (in the case where the √SWAP is a basic two qubit gate).

FIG. 14A is a schematic diagram of a concrete configuration method of a lateral two qubit gate section (04123) (in the case where the CZ gate is a basic two qubit gate).

FIG. 14B is a schematic diagram of a concrete configuration method of the lateral two qubit gate section (04123) (in the case where the CROT is a basic two qubit gate).

FIG. 14C is a schematic diagram of a concrete configuration method of the lateral two qubit gate section (04123) (in the case where the √SWAP is a basic two qubit gate).

FIG. 15A is a schematic diagram of a concrete configuration method of a measurement section (04200) (parallel measurement type).

FIG. 15B is a schematic diagram of a concrete configuration method of the measurement section (04200) (stepped type).

FIG. 15C is a schematic diagram of a concrete configuration method of the measurement section (04200) (integrated measurement type).

FIG. 16A is a quantum circuit diagram for depicting quantum computation processing including the H gate according to the embodiment.

FIG. 16B is a schematic diagram of a device for implementing the quantum computation processing including the H gate according to the embodiment.

FIG. 16C is a table diagram for depicting a circuit model command for physical quantum bits upon implementing the quantum computation processing including the H gate according to the embodiment.

FIG. 16D is a table diagram for depicting a measurement axis command programmed to implement the quantum computation processing including the H gate according to the embodiment.

FIG. 17A is a quantum circuit diagram for depicting quantum computation processing including the S gate according to the embodiment.

FIG. 17B is a table diagram for depicting a measurement axis command programmed to implement the quantum computation processing including the S gate according to the embodiment.

FIG. 18A is a quantum circuit diagram for depicting quantum computation processing including an I gate according to the embodiment.

FIG. 18B is a table diagram for depicting a measurement axis command programmed to implement the quantum computation processing including the I gate according to the embodiment.

FIG. 19A is a quantum circuit diagram for depicting quantum computation processing including a Uᵣₒₜ gate according to the embodiment.

FIG. 19B is a table diagram for depicting a measurement axis command programmed to implement the quantum computation processing including the Uᵣₒₜ gate according to the embodiment.

FIG. 20A is a quantum circuit diagram for depicting quantum computation processing including a CNOT gate according to the embodiment.

FIG. 20B is a schematic diagram of a device for implementing the quantum computation processing including the CNOT gate according to the embodiment.

FIG. 20C is a table diagram for depicting a circuit model command for physical quantum bits upon implementing the quantum computation processing including the CNOT gate according to the embodiment.

FIG. 20D is a table diagram for depicting a measurement axis command programmed to implement the quantum computation processing including the CNOT gate according to the embodiment.

FIG. 21A is a quantum circuit diagram for depicting quantum computation processing including a T gate, the Uᵣₒₜ gate as optional single qubit rotation, and the CNOT gate according to the embodiment.

FIG. 21B is a table diagram for depicting a circuit model command for physical quantum bits upon implementing the quantum computation processing including the T gate, the Uᵣₒₜ gate as optional single qubit rotation, and the CNOT gate according to the embodiment.

FIG. 21C is a table diagram for depicting a measurement axis command programmed to implement the quantum computation processing including the T gate, the Uᵣₒₜ gate as optional single qubit rotation, and the CNOT gate according to the embodiment.

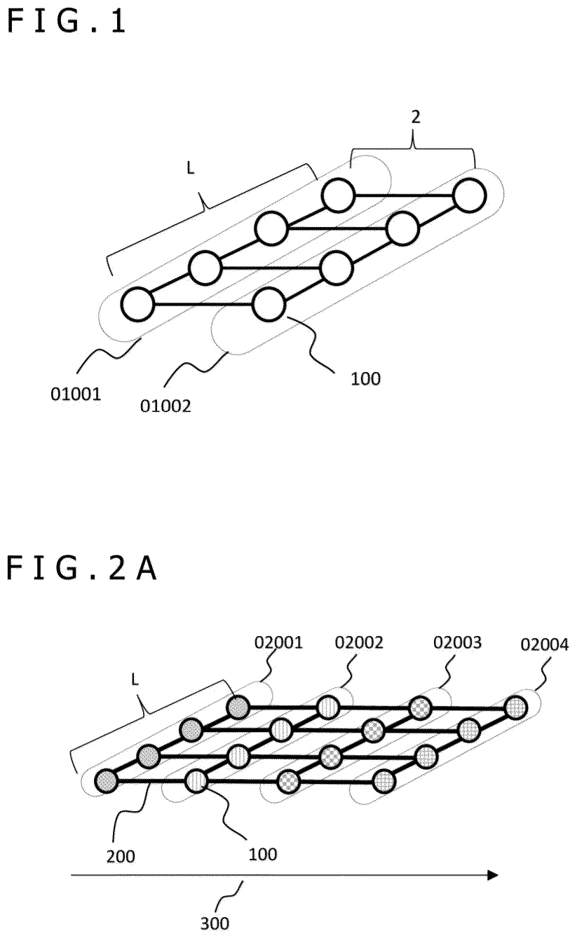

### MODES FOR CARRYING OUT THE INVENTION

Embodiments of the present invention will be described in detail by using the drawings. However, the present invention should not be interpreted by being limited to the content of the description of the following embodiments. It can easily be understood by those skilled in the art that the detailed configuration can be changed without departing from the idea or gist of the present invention.

In the configuration according to the embodiments described below, the same reference signs are used for the same parts or parts having similar functions among different drawings, and duplicate descriptions may be omitted.

In the case where there are a plurality of elements having the same or similar functions, the explanation may be made by giving them the same reference signs with different subscripts added thereto. However, in the case where there is no need to distinguish those elements from one another, the explanation may be made with no subscript added thereto.

Expressions such as “first,” “second,” and “third” in the present specification are used to identify constitutional elements, and do not necessarily limit the number, order, or content thereof. In addition, numerals are used to identify constitutional elements for each context, and numerals used in one context do not necessarily indicate the same configurations in other contexts. Moreover, a constitutional element identified by a certain numeral is not prevented from also functioning as another constitutional element identified by another numeral.

The position, size, shape, range, and the like of each configuration depicted in the drawings and the like do not represent the actual position, size, shape, range, and the like in some cases in order to facilitate understanding of the invention. Therefore, the present invention is not necessarily limited to the positions, sizes, shapes, ranges, and the like disclosed in the drawings and the like.

Publications, patents, and patent applications cited in the present specification directly configure part of the description of the present specification.

Constitutional elements represented in a singular form in the present specification include a plural form unless specifically indicated in the context.

In the embodiments described below, the spin of a single electron confined in a quantum dot is used as a quantum bit. For example, in a device in which a plurality of quantum dots to which the semiconductor technology is applied are present, the gate voltages and barrier potential voltages of the quantum dots are appropriately changed, so that an electron can be moved from a quantum dot containing an electron to an adjacent quantum dot containing no electron without changing the electron spin state. This operation is called shuttling (for example, Non Patent Document 3).

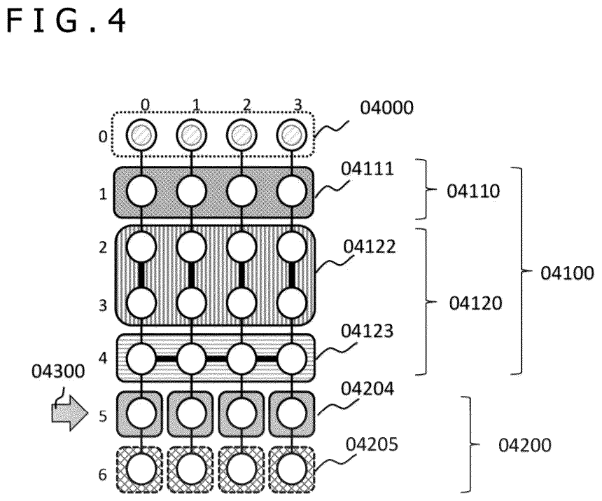

FIG. 4 is a schematic diagram of a device according to an embodiment in which one way quantum computation is implemented by shuttling. Here, a quantum dot array is assumed to have two or more columns of quantum dot lines having a plurality of quantum dots and extending in one direction. With respect to concrete examples of executing shuttling and concrete examples of a device to which the semiconductor technology is applied, the above prior art documents and the like are referred to, and they will not be mentioned in detail in the present specification.

As depicted in FIG. 4, in order to operate physical quantum bits generated in a physical quantum bit generation section (04000), used is a quantum dot array configured with two sections: a cluster state generation section (04100) including a single qubit gate section (04111), a longitudinal two qubit gate section (04122), and a lateral two qubit gate section (04123); and a measurement section (04200) including an XY single qubit gate section (04204) and a Z measurement section (04205). Electrons that are quantum bits always move in the direction from the cluster state generation section (04100) toward the measurement section (04200) by a shuttling operation.

The above-described cluster state generation section (04100) further includes two sections. The first one is a |+> state generation section (04110) that is configured with the single qubit gate section (04111) that performs a single qubit gate operation necessary for generating a o|+> state. The second one is an entanglement generation section (04120) that generates entanglement by forming a CZ gate between quantum bits adjacent in a lattice shape.

In the entanglement generation section (04120), two kinds of two qubit gates, i.e., the longitudinal two qubit gate section (04122) that performs a CZ gate operation in a direction parallel to the quantum dot line and the lateral two qubit gate section (04123) that performs a CZ gate operation in a direction perpendicular to the quantum dot line, are arranged in random order.

The cluster state generation section (04100) includes the |+> state generation section (04110) and the entanglement generation section (04120) in this order, and electrons that are quantum bits always move from the |+> state generation section (04110) toward the entanglement generation section (04120) by a shuttling operation.

The above-described measurement section (04200) performs measurement by the basis B(φⱼ) of (Equation 3). The measurement section (04200) includes the two sections according to the decomposition of (Equation 4).

The first one is the XY single qubit gate section (04204) that implements U_{M}(φⱼ) given by (Equation 5). The XY single qubit gate section (04204) can be operated rotationally around an arbitrary axis. In the gate operation, the value of a rotation angle φⱼ differs according to quantum computation processing to be executed. The value of the rotation angle φⱼ is specified in advance as a program (04300).

The second one is the Z measurement section (04205). In the measurement section (04200), electrons that are quantum bits always move from the XY single qubit gate section (04204) toward the Z measurement section (04205) by a shuttling operation.

Next, quantum computation processing using the above-described device will be described. By moving electrons in one direction by shuttling and continuing to supply the electrons that are physical quantum bits, the number of computation resources that can be executed can be increased by spread of time.

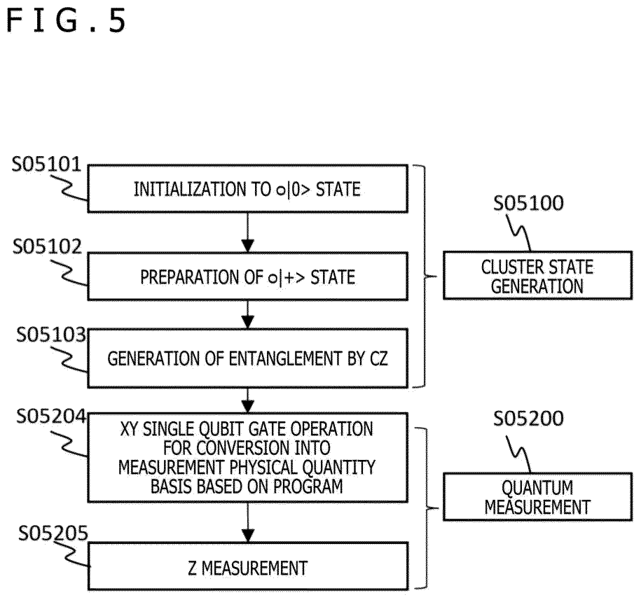

FIG. 5 summarizes processing necessary for the one way quantum computation. The one way quantum computation is implemented by roughly two processes. That is, two processes of cluster state generation (S05100) and quantum measurement (S05200) that requires a program for quantum computation to be performed are necessary.

The cluster state generation (S05100) further includes three processes. First, quantum bits are initialized to a o|0> state (S05101), and an operation of a single qubit gate is performed for the quantum bits by, for example, an H gate to form a o|+> state (S05102). By performing an operation of a CZ gate between adjacent quantum bits in the o|+> state, a quantum state with high entanglement called a cluster state can be obtained (S05103). The quantum computation processing is implemented by the quantum measurement (S05200) that measures the cluster state of the quantum bits by the basis B(φⱼ) of (Equation 3) according to an operation to be executed.

The quantum measurement (S05200) includes two processes, that is, an XY single qubit operation (S05204) for conversion to the basis B(φⱼ) of (Equation 3) and Z measurement (S05205).

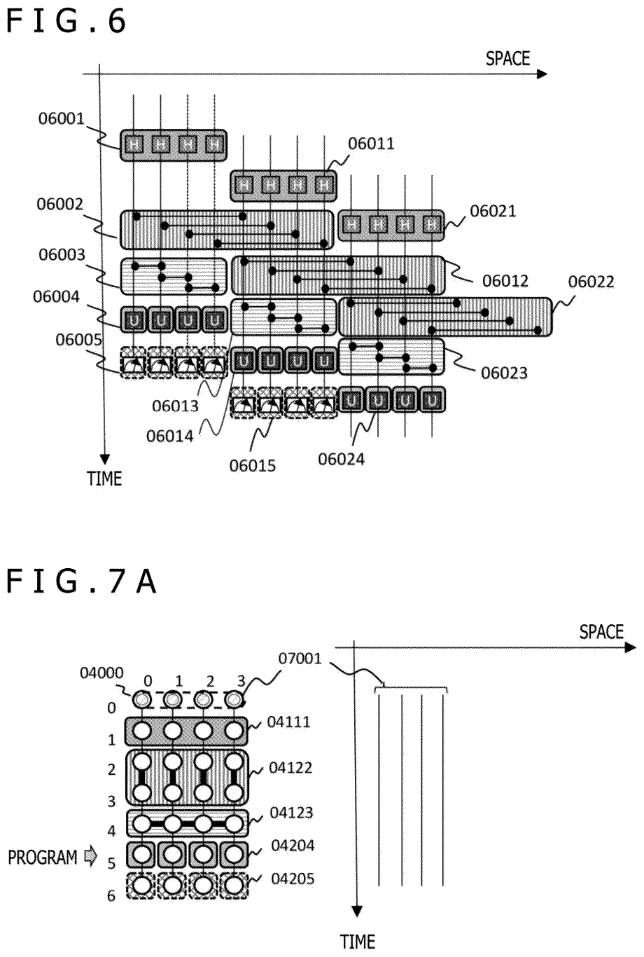

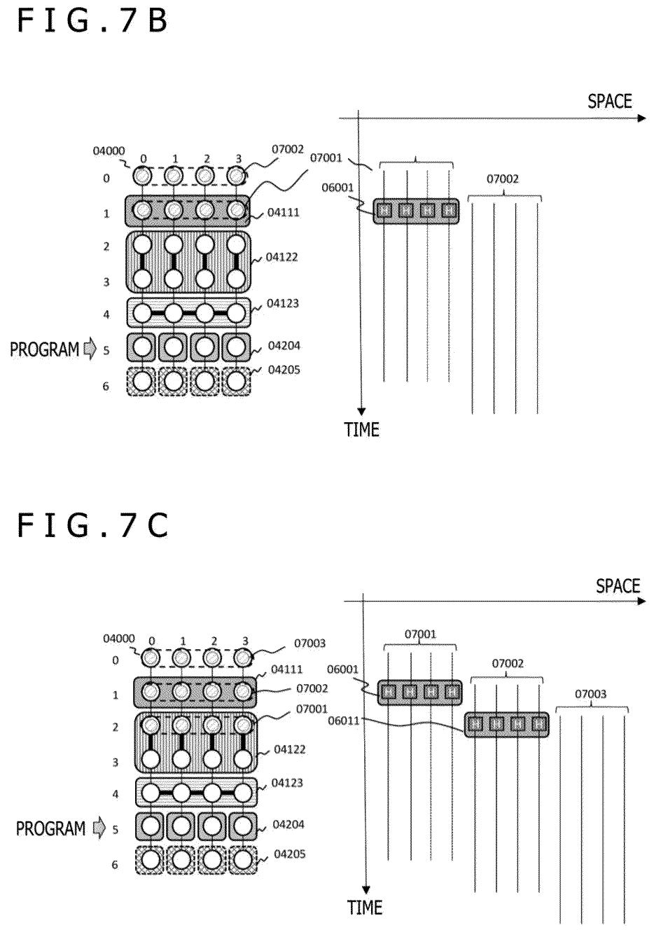

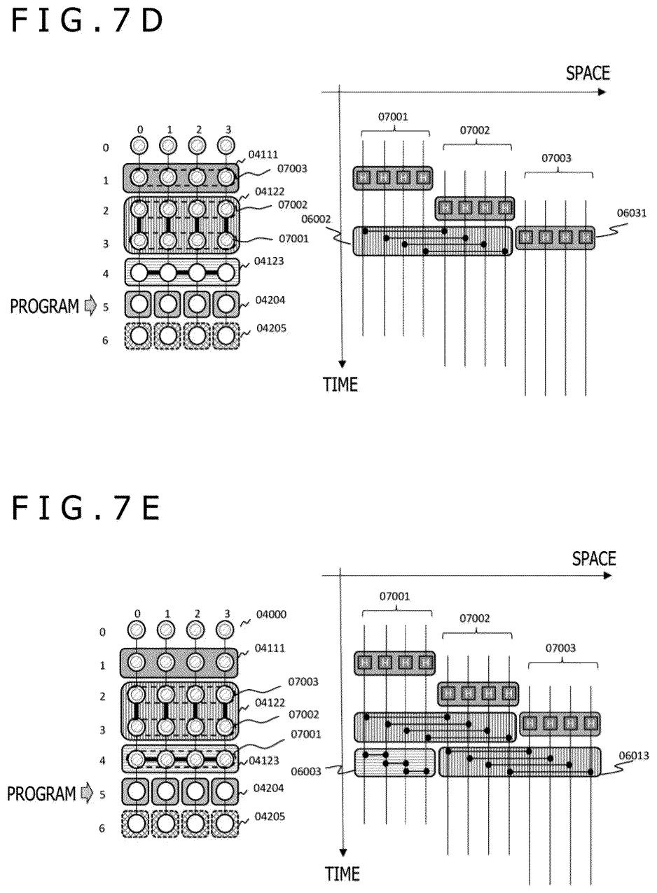

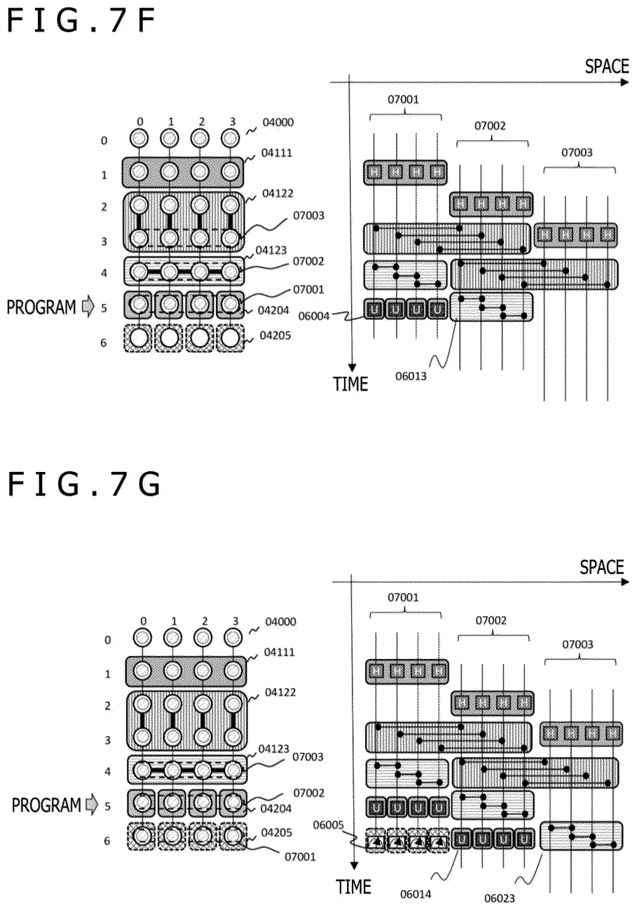

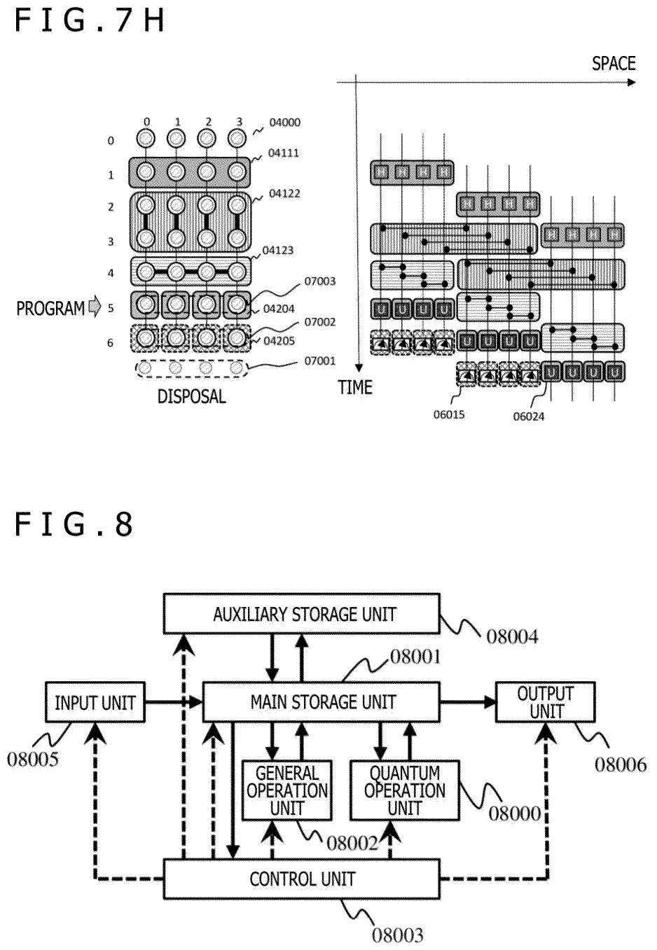

FIG. 6 and FIG. 7A to FIG. 7H are quantum circuit diagrams in which concreate examples for executing the processing of FIG. 5 by using the device of FIG. 4 are summarized.

FIG. 6 depicts a flow of the entire processing. FIG. 7A to FIG. 7H are circuit diagrams depicting a state of movement of electrons that are physical quantum bits in the device of FIG. 4 in each time step and a quantum operation performed for the physical quantum bits in each time step. In all the drawings, the horizontal axis represents space, and the vertical axis represents time. In the device of FIG. 4, it is assumed that electrons that are physical quantum bits always flow from the upper side to the lower side of each drawing.

As depicted in FIG. 7A, electrons (07001) are induced in the physical quantum bit generation section (04000) of FIG. 4, so that physical quantum bits are prepared (S05101).

As depicted in FIG. 7B, the electrons (07001) that are physical quantum bits are moved to the single qubit gate section (04111) located one row below by shuttling, and are further subjected to a single qubit gate operation (06001) of the processing (S05102) to become the state o|+>. Simultaneously with the above-described shuttling, new electrons (07002) are induced in the physical quantum bit generation section (04000).

As depicted in FIG. 7C, the electrons (07001) in the single qubit gate section (04111) are moved to the upper stage of the longitudinal two qubit gate section (04122), and then, the electrons (07002) in the physical quantum bit generation section (04000) are moved to the single qubit gate section (04111). Further, the electrons (07002) are subjected to a single qubit gate operation (06011) of the processing (S05102) in the single qubit gate section (04111). At the same time, electrons (07003) are newly induced in the physical quantum bit generation section (04000).

As depicted in FIG. 7D, after the electrons (07001) in the upper stage of the longitudinal two qubit gate section (04122) are moved to the lower stage of the longitudinal two qubit gate section (04122), the electrons (07002) in the single qubit gate section (04111) are moved to the upper stage of the longitudinal two qubit gate section (04122), and further, the electrons (07003) in the physical quantum bit generation section (04000) are moved to the single qubit gate section (04111). When it is confirmed that the electrons are placed in the longitudinal two qubit gate section (04122), a longitudinal two qubit operation (06002) of the processing (S05103) is performed. At the same time, electrons are newly induced in the physical quantum bit generation section (04000), and a single qubit gate operation (06031) of the processing (S05102) is performed in the single qubit gate section (04111).

As depicted in FIG. 7E, the electrons (07001) in the lower stage of the longitudinal two qubit gate section (04122) are moved to the lateral two qubit gate section (04123), the electrons (07002) in the upper stage of the longitudinal two qubit gate section (04122) are moved to the lower stage of the longitudinal two qubit gate section (04122), the electrons (07003) in the single qubit gate section (04111) are moved to the upper stage of the longitudinal two qubit gate section (04122), and electrons (not illustrated) in the physical quantum bit generation section (04000) are moved to the single qubit gate section (04111). The electrons (07001) in the lateral two qubit gate section (04123) are subjected to a lateral two qubit operation (06003) of the processing (S05103). At this time, a single qubit gate operation (not illustrated) and a two qubit gate operation (06013) are simultaneously performed in the single qubit gate section (04111) and the longitudinal two qubit gate section (04122), and electrons are newly induced in the physical quantum bit generation section (04000). The order and positions of the two qubit gate operations in the longitudinal two qubit gate section (04122) and the lateral two qubit gate section (04123) in which the processing (S05103) is performed can be switched.

As depicted in FIG. 7F, the electrons (07001) in the lateral two qubit gate section (04123) are moved to the XY single qubit gate section (04204), the electrons (07002) in the lower stage of the longitudinal two qubit gate section (04122) are moved to the lateral two qubit gate section (04123), the electrons (07003) in the upper stage of the longitudinal two qubit gate section (04122) are moved to the lower stage of the longitudinal two qubit gate section (04122), the electrons in the single qubit gate section (04111) are moved to the upper stage of the longitudinal two qubit gate section (04122), and the electrons in the physical quantum bit generation section (04000) are moved to the single qubit gate section (04111). In each quantum dot of the XY single qubit gate section (04204), an XY single qubit gate operation (06004) for implementing the programmed U_{M}(φⱼ) is performed for the electrons (07001), and conversion to the measurement basis B(φⱼ) is performed by the processing (S05204). At the same time, the predetermined quantum gate operation (06013) or the like is executed in each of the physical quantum bit generation section (04000), the single qubit gate section (04111), the longitudinal two qubit gate section (04122), and the lateral two qubit gate section (04123).

As depicted in FIG. 7G, the electrons (07001) in the XY single qubit gate section (04204) are moved to the Z measurement section (04205), the electrons (07002) in the lateral two qubit gate section (04123) are moved to the XY single qubit gate section (04204), and the electrons (07003) in the lower stage of the longitudinal two qubit gate section (04122) are moved to the lateral two qubit gate section (04123). Further, the electrons in the upper stage of the longitudinal two qubit gate section (04122), the electrons in the single qubit gate section (04111), and the electrons in the physical quantum bit generation section (04000) are moved to the lower stage of the longitudinal two qubit gate section (04122), the upper stage of the longitudinal two qubit gate section (04122), and the single qubit gate section (04111), respectively. The electrons (07001) in the Z measurement section (04205) are subjected to Z measurement (06005) of the processing (S05205). At the same time, a predetermined quantum operation (06023) or the like is executed in each of the physical quantum bit generation section (04000), the single qubit gate section (04111), the longitudinal two qubit gate section (04122), and the lateral two qubit gate section (04123), and an operation (06014) according to the program is performed in the XY single qubit gate section (04204).

As depicted in FIG. 7H, the electrons (07001) in the Z measurement section (04205) are measured and disposed of, the electrons (07002) in the XY single qubit gate section (04204) are moved to the Z measurement section (04205), and the electrons (07003) in the lateral two qubit gate section (04123) are moved to the XY single qubit gate section (04204). Further, the electrons in the lower stage of the longitudinal two qubit gate section (04122), the electrons in the upper stage of the longitudinal two qubit gate section (04122), the electrons in the single qubit gate section (04111), and the electrons in the physical quantum bit generation section (04000) are moved to the lateral two qubit gate section (04123), the lower stage of the longitudinal two qubit gate section (04122), the upper stage of the longitudinal two qubit gate section (04122), and the single qubit gate section (04111), respectively. A predetermined quantum gate operation is performed in each section, and an operation according to the program is performed in the XY single qubit gate section (04204). The one way quantum computation is implemented by repeating the above processes.

According to the embodiment described above, by moving electrons that are physical quantum bits by shuttling, it is possible to arrange a plurality of kinds of necessary operations in different portions of the device. Accordingly, the accuracy of each gate operation can be improved, and the circuit area necessary for a quantum device operation can be reduced.

In addition, by continuously inducing electrons that are physical quantum bits and disposing of them after the quantum operation, it is possible to continuously increase physical quantum bits that are computation resources in a limited device area. Moreover, by repeating induction and disposal of electrons, quantum computation processing that takes time longer than coherent time can be implemented.

In the case where quantum bits are moved by shuttling, it is necessary to determine the optimum movement path according to a desired operation. In the present embodiment, by performing the shuttling and the one way quantum computation in combination, the movement path and the length of the movement path can be made constant in all the logical qubits. Accordingly, prior classical computation to define the movement path of quantum bits is not necessary, the effect of an error caused by shuttling movement can be made uniform, and the computation accuracy of the entire quantum computation processing can be kept constant.

A supplementary explanation of the structure of the device is given. As depicted in FIG. 4, the qubit array is configured with two sections: the cluster state generation section (04100) including the single qubit gate section (04111), the longitudinal two qubit gate section (04122), and the lateral two qubit gate section (04123); and the measurement section (04200) including the XY single qubit gate section (04204) for implementing the gate operation U_{M}(φⱼ) determined by a program given from the outside and the Z measurement section (04205). In the qubit array, a shuttling operation is always performed in one direction from the cluster state generation section to the measurement section. Such a qubit array is a form of the device according to the embodiment. Note that the positions of the longitudinal two qubit gate section (04122) and the lateral two qubit gate section (04123) can be switched.

The device according to the embodiment and the control method thereof can be configured by applying the semiconductor technology disclosed in Patent Document 1, for example. The explanations of known elemental technologies are omitted. Supplementary explanations of the processing processes and necessary systems are given.

FIG. 8 is a block diagram of a system used in the case where the one way quantum computation is performed using the device of FIG. 4.

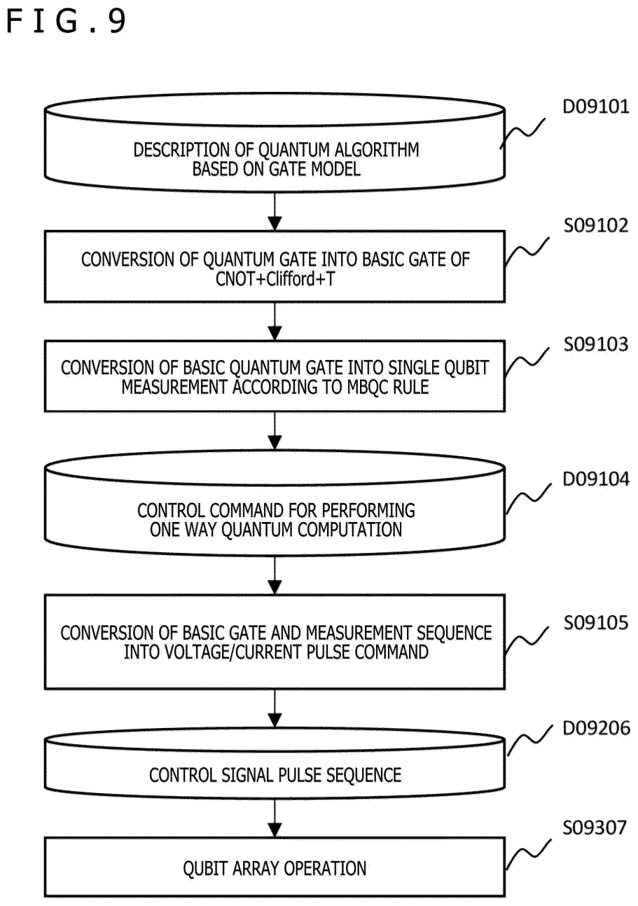

FIG. 9 depicts a flow of computation processing performed using the system of FIG. 8.

The system in FIG. 8 is different from a general computation unit in that it has a quantum operation unit (08000). The basic configuration of the quantum operation unit (08000) is as described up to FIG. 7H. FIG. 9 summarizes a flow of processing necessary for performing quantum computation according to the method proposed in the embodiment by using such a system as described above.

A program (D09101) describing a quantum algorithm based on a gate model is input to a main storage unit (08001) through an input unit (08005). A general operation unit (08002) and a control unit (08003) are used to perform processing of transpiling a quantum gate into a basic operator set, that is, a CNOT+Clifford+T gate, which can easily be executed in the one way quantum computation (S09102). The general operation unit (08002) and the control unit (08003) may be integrated as a processing unit, or some of them may be configured by software.

Further, the general operation unit (08002) and the control unit (08003) set the rotation angle φⱼ of the measurement basis B(φⱼ) given by (Equation 3) using the transpilation result (S09103), convert the basic quantum gate into single qubit measurement according to the MBQC rule, and convert it into a control command (D09104) for performing the one way quantum computation for a unit for controlling a qubit array.

According to the control command, the basic gate and a measurement sequence are converted into a voltage/current pulse command (S09105) and thus converted into a control signal pulse sequence (D09106). The resultant sequence is transferred to a unit for controlling a qubit array in the control unit (08003). According to the control signal pulse sequence (D09106), the control unit (08003) transmits a control pulse sequence with microwaves and voltage signals necessary for executing the shuttling, the single qubit gate, the two qubit gate, and the measurement operation (09206). The pulses as analog signals are used to cause the qubit array to operate (09107).

A supplementary explanation of the operation method is given. As depicted in FIG. 7A to FIG. 7H, the processing of FIG. 5 is performed by alternately performing the shuttling and the quantum operation to implement desired quantum computation. That is, the processing of (S05101) is performed in the physical quantum bit generation section (04000), the processing of (S05102) is performed in the single qubit gate section (04111), the processing of (S05103) is performed in the longitudinal two qubit gate section (04122) and the lateral two qubit gate section (04123), the processing of (S05204) is performed in the XY single qubit gate section (04204) operated according to the program (04300), and the processing of (S05205) is performed in the Z measurement section (04205).

Other than the processing of (S05204), operations always performed for each place during the quantum computation processing are fixed. Therefore, the control command (D09104) can fix commands other than those related to the XY single qubit gate operation (S05204) for conversion to the measurement physical quantity basis based on the program. The shuttling path in one direction is fixed without being changed by an operation, and the rotation angle φⱼ of the measurement basis B(φⱼ) and the measurement physical quantity are set by the control command (D09104) according to the operation to be performed. Accordingly, the load on software of the system is reduced.

The operations necessary for the one way quantum computation depicted in FIG. 5 correspond to functions of the respective portions of the device of FIG. 4. In particular, the operation other than the processing of (S05204) performed in the XY single qubit gate section (04204) is fixed for each operation place. Therefore, the control signal pulse sequence (D09106) of FIG. 9 represents only a real number sequence that summarizes the code of shuttling, the timing to perform the operation, and information of the parameter φⱼ that determines the measurement basis given to the measurement section (04200).

### First Embodiment

As a first embodiment, a basic structure of a device for implementing quantum computation will be described in detail. As depicted in FIG. 4, the device proposed in the embodiment includes two sections, i.e., the cluster state generation section (04100) and the measurement section (04200). In the following (Example 1-1: cluster state generation section), 24 configuration methods of the cluster state generation section are presented, and in (Example 1-2: measurement section), three configuration methods of the measurement section are presented. Since the cluster state generation section and the measurement section can be configured independently of each other, a total of 72 configuration methods are presented.

### Example 1-1: Cluster State Generation Section

Here, a total of 24 examples of the structure of the cluster state generation section are given. The cluster state generation section (04100) further includes two sections, i.e., the |+> state generation section (04110) and the entanglement generation section (04120). In (Example 1-1-1: |+> state generation section), two configuration methods of the |+> state generation section (04110) are presented. In (Example 1-1-2: entanglement generation section), a total of 12 configuration methods of the entanglement generation section (04120) are presented. The |+> state generation section (04110) and the entanglement generation section (04120) can be designed independently of each other, and 24 (2×12) configuration methods are thus conceivable.

### Example 1-1-1: |+> State Generation Section

As a method of converting the quantum state |0> into |+>, one device structure and two gate operations are available.

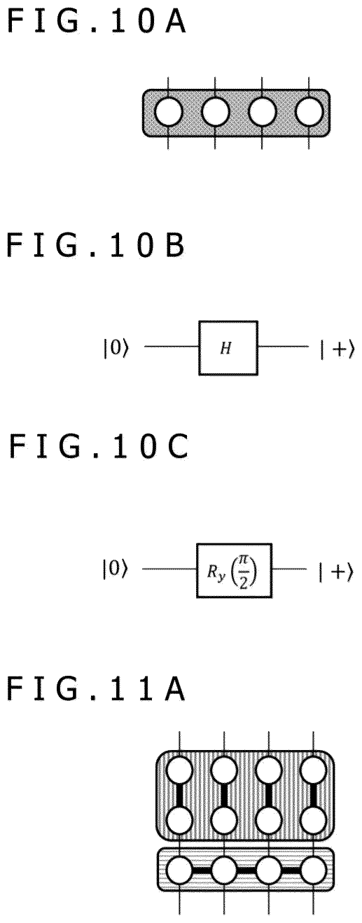

FIG. 10A depicts a device structure example of the |+> state generation section (04110).

FIG. 10B depicts a method of conversion from |0> to |+> by an H gate, and the quantum state changes as depicted in (Equation 12).

$$\begin{matrix}[ Math . 12 ] & \\ H \vert 0 〉 = \frac{1}{\sqrt{2}} [ \begin{matrix}1 & 1 \\ 1 & - 1\end{matrix} ] [ \begin{matrix}1 \\ 0\end{matrix} ] = \frac{1}{\sqrt{2}} [ \begin{matrix}1 \\ 1\end{matrix} ] & ( Equation 12 )\end{matrix}$$

FIG. 10C depicts a method of conversion from |0> to |+> by an Ry(π/2) gate, and the quantum state changes as depicted in (Equation 13).

$$\begin{matrix}[ Math . 13 ] & \\ {R}_{y} ( π / 2 ) \vert 0 〉 = \frac{1}{\sqrt{2}} [ \begin{matrix}1 & - 1 \\ 1 & 1\end{matrix} ] [ \begin{matrix}1 \\ 0\end{matrix} ] = \frac{1}{\sqrt{2}} [ \begin{matrix}1 \\ 1\end{matrix} ] & ( Equation 13 )\end{matrix}$$

Note that the Ry(π/2) gate is given by the matrix of (Equation 14).

$$\begin{matrix}[ Math . 14 ] & \\ {R}_{y} ( π / 2 ) = \frac{1}{\sqrt{2}} [ \begin{matrix}1 & - 1 \\ 1 & 1\end{matrix} ] & ( Equation 14 )\end{matrix}$$

Therefore, there are two device structures for converting the quantum state |0> to |+>.

### Example 1-1-2: Entanglement Generation Section

In the cluster state necessary for the one way quantum computation, quantum bits are entangled in a lattice shape. Therefore, in the device of FIG. 4, it is necessary to generate entanglement by acting the CZ gate in the longitudinal direction and the lateral direction.

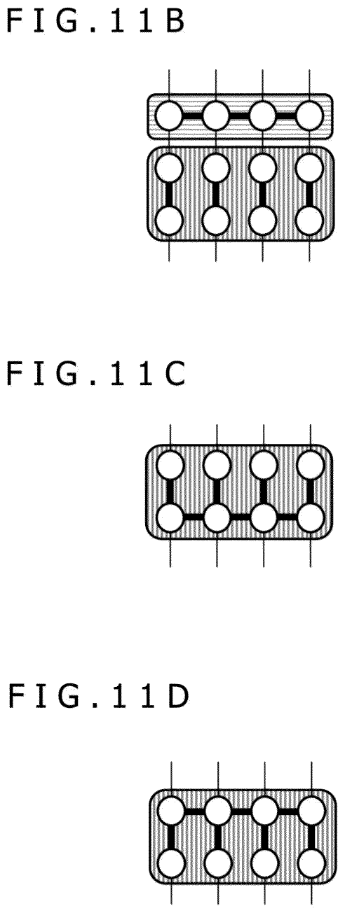

FIG. 11A to FIG. 11D depict various longitudinal and lateral two qubit gate operations. The longitudinal and lateral two qubit gate operations are performed in random order, and there are four possible arrangements, such as longitudinal→lateral coupling in FIG. 11A, lateral→longitudinal coupling in FIG. 11B, longitudinal & lateral coupling in FIG. 11C, and lateral & longitudinal coupling in FIG. 11D.

A CROT gate and a √SWAP gate are known as basic two qubit gates that can be implemented in quantum dot systems.

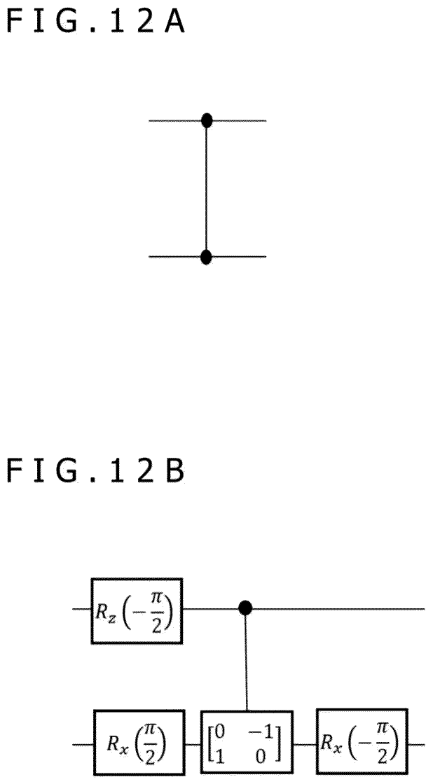

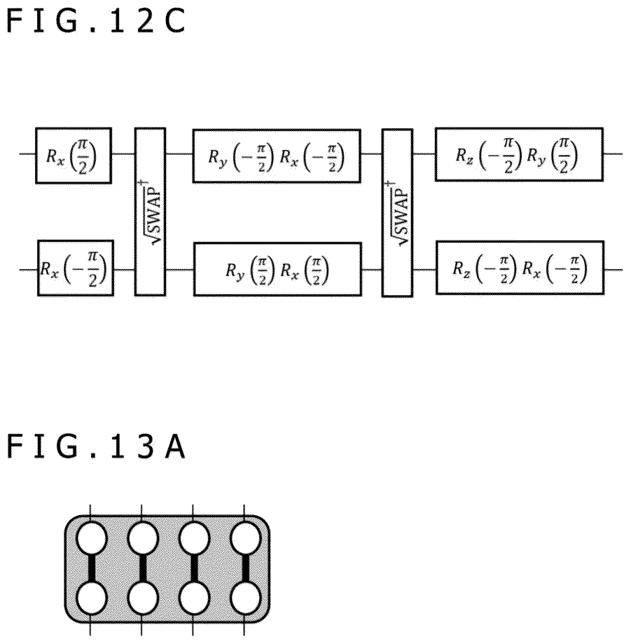

FIG. 12A to FIG. 12C depict various methods for implementing a CZ gate. There are three possible methods, that is, a method for implementing a CZ gate with a single CZ gate in FIG. 12A, a method for implementing a CZ gate with an equivalent circuit having a combination of a CROT gate and a single qubit gate in FIG. 12B, and a method for implementing a CZ gate with an equivalent circuit having a combination of a √SWAP^{†} gate and a single qubit gate in FIG. 12C.

Note that the CROT gate is given by the matrix of (Equation 15).

$$\begin{matrix}[ Math . 15 ] & \\ [ \begin{matrix}1 & 0 & 0 & 0 \\ 0 & 1 & 0 & 0 \\ 0 & 0 & 0 & - 1 \\ 0 & 0 & 1 & 0\end{matrix} ] & ( Equation 15 )\end{matrix}$$

Note that the √SWAP gate and √SWAP^{†} are given by the following matrixes.

$$\begin{matrix}[ Math . 16 ] & \\ \sqrt{SWAP} = [ \begin{matrix}1 & 0 & 0 & 0 \\ 0 & \frac{1 + {e}^{- i π / 2}}{2} & \frac{1 - {e}^{- i π / 2}}{2} & 0 \\ 0 & \frac{1 - {e}^{- i π / 2}}{2} & \frac{1 + {e}^{- i π / 2}}{2} & 0 \\ 0 & 0 & 0 & 1\end{matrix} ] & ( Equation 16 )\end{matrix}$$

$$\begin{matrix}[ Math . 17 ] & \\ {( \sqrt{SWAP} )}^{†} = [ \begin{matrix}1 & 0 & 0 & 0 \\ 0 & \frac{1 + {e}^{i π / 2}}{2} & \frac{1 - {e}^{i π / 2}}{2} & 0 \\ 0 & \frac{1 - {e}^{i π / 2}}{2} & \frac{1 + {e}^{i π / 2}}{2} & 0 \\ 0 & 0 & 0 & 1\end{matrix} ] & ( Equation 17 )\end{matrix}$$

The arrangements of FIG. 11A to FIG. 11D and the equivalent circuits of FIG. 12A to FIG. 12C are independent of each other, and it can be understood that a total of 12 methods are available as a method for generating the cluster state by generating entanglement.

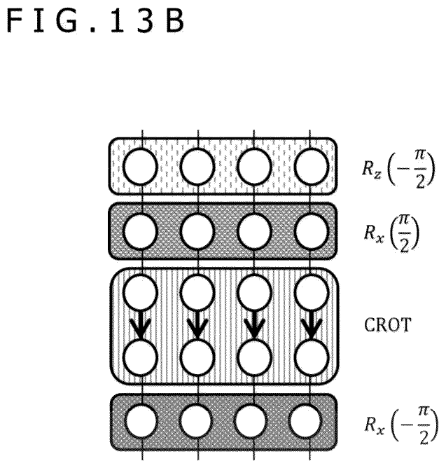

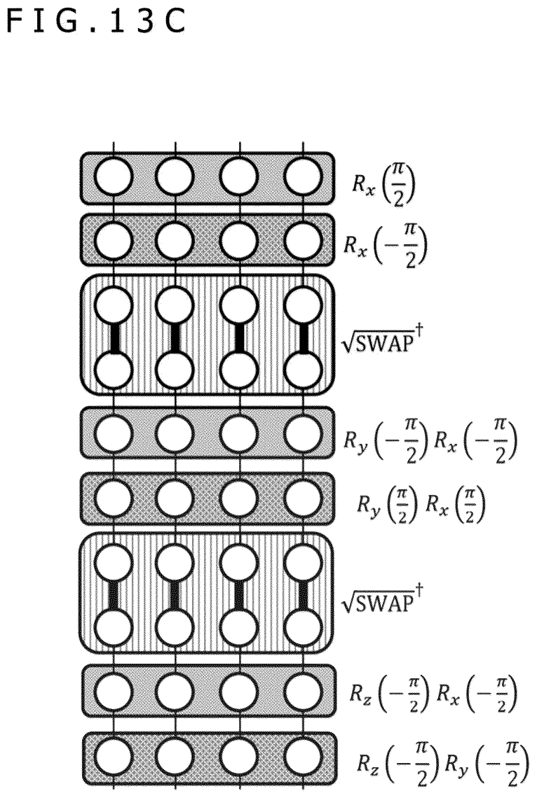

FIG. 13A to FIG. 13C specifically depict gate arrangements for implementing the CZ equivalent circuits depicted in FIG. 12A to FIG. 12C when longitudinal entanglement coupling is formed. FIG. 13A depicts a method for implementing the equivalent circuit with a single CZ gate, FIG. 13B depicts a CZ equivalent circuit having a combination of a CROT gate and a single qubit gate, and FIG. 13C depicts a CZ equivalent circuit having a combination of a √SWAP^{†} gate and a single qubit gate.

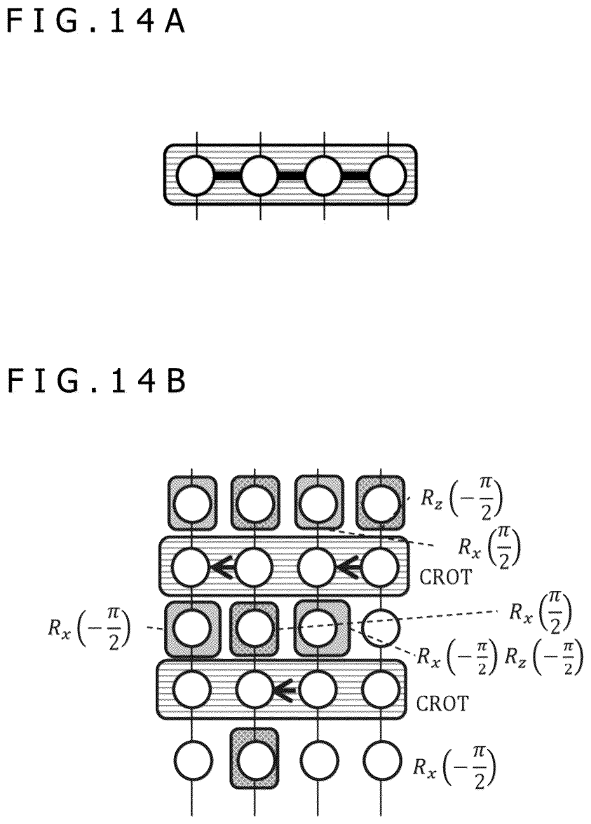

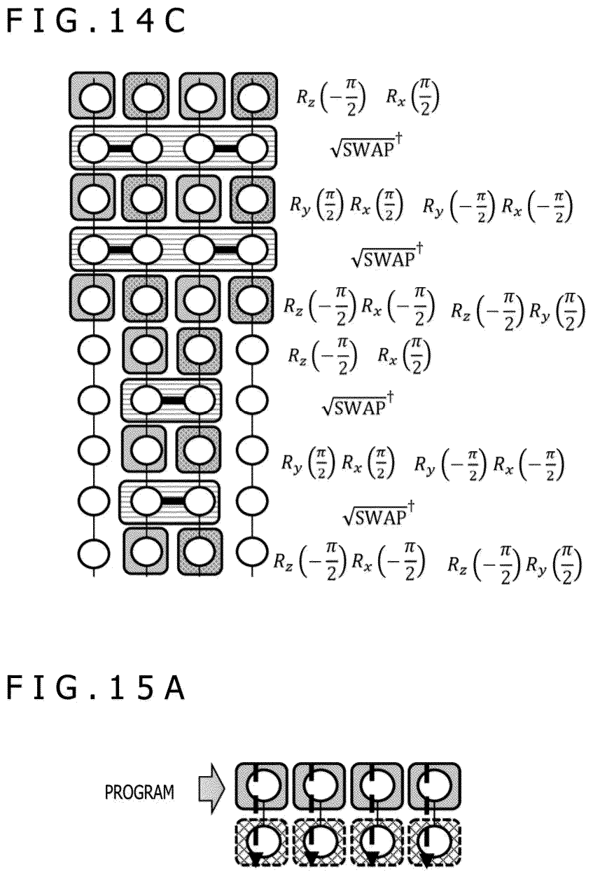

FIG. 14A to FIG. 14C specifically depict gate arrangements for implementing the CZ equivalent circuits depicted in FIG. 12A to FIG. 12C when lateral entanglement coupling is formed. FIG. 14A depicts a method for implementing the equivalent circuit with a single CZ gate, FIG. 14B depicts a CZ equivalent circuit having a combination of a CROT gate and a single qubit gate, and FIG. 14C depicts a CZ equivalent circuit having a combination of a √SWAP^{†} gate and a single qubit gate.

### Example 1-2: Structure of Measurement Section

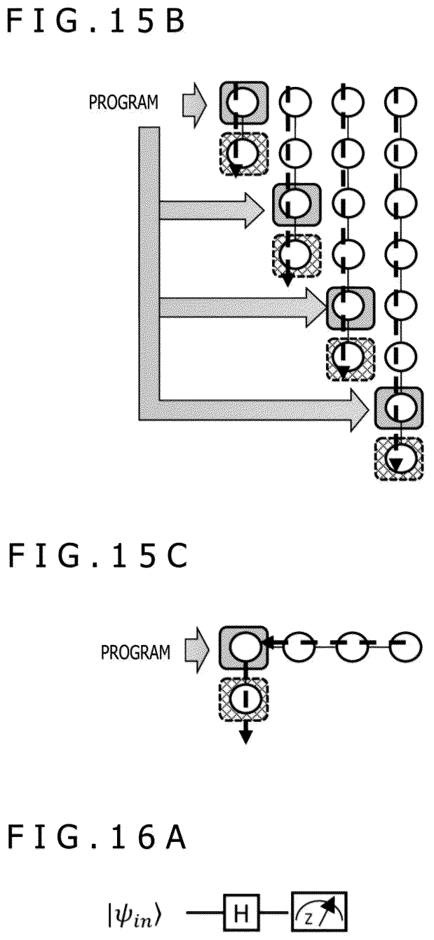

In FIG. 15A to FIG. 15C, a total of three examples of the structure of the measurement section are given. The measurement section is configured with the single qubit operation U_{M}(φⱼ) given by (Equation 5) and the Z measurement. The measurement section can be arranged in three ways, that is, a parallel measurement type in FIG. 15A, a stepped type in FIG. 15B, and integrated measurement type in FIG. 15C.

In FIG. 15A to FIG. 15C, an input of an axial rotation program is indicated by a thick arrow, and the direction of shuttling is indicated by a dotted arrow.

### Second Embodiment

As a second embodiment, operations necessary for implementing concrete quantum computation processing will be described in detail. Performing the process of in FIG. 6 by using the device of FIG. 4 enables quantum computation. Here, a more concrete example of the process in FIG. 6 will be presented.

### (Example 2-1) Quantum Computation Processing Including H-Gate

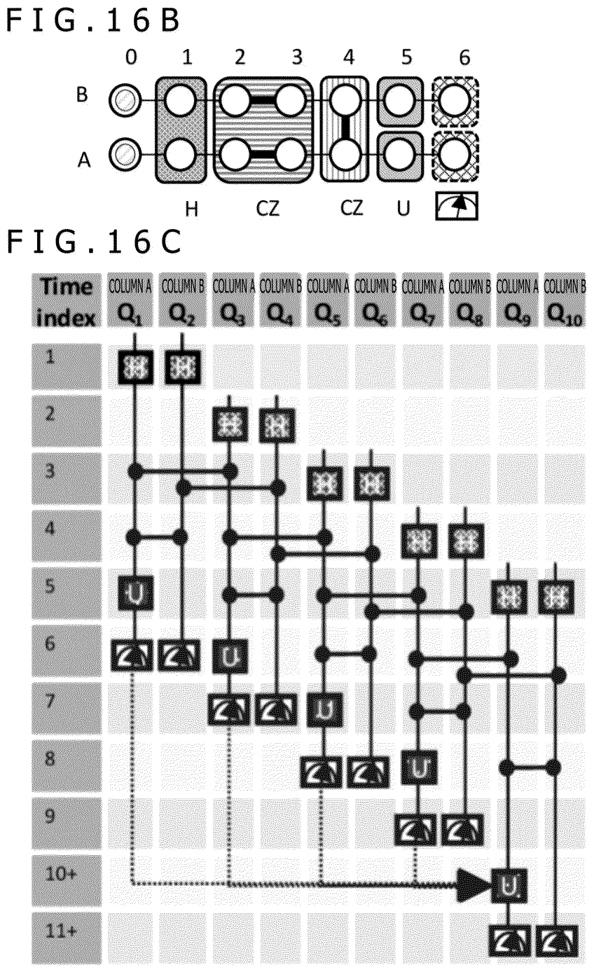

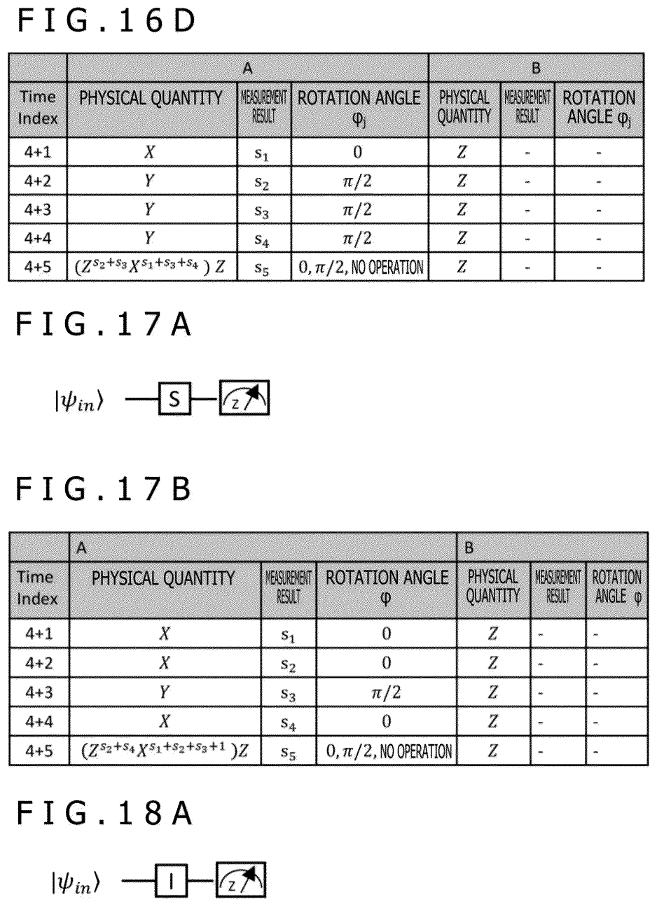

FIG. 16A depicts a quantum circuit assumed in this example. A case of performing an H gate and Z measurement for logical qubits is assumed.

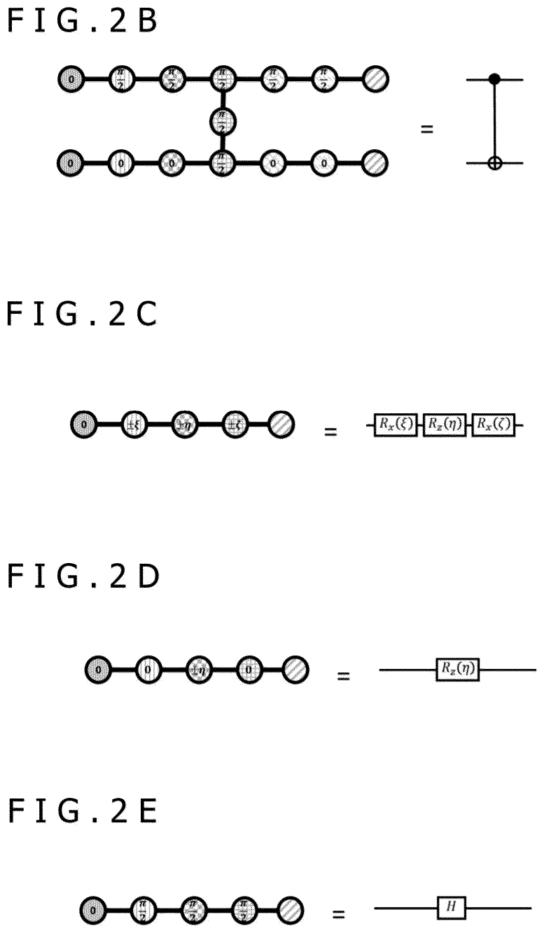

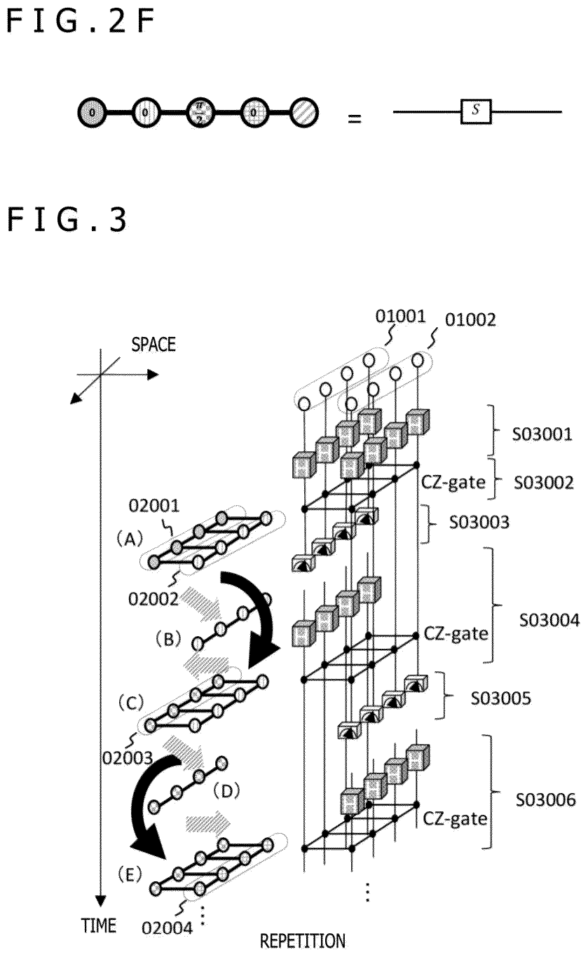

FIG. 16B depicts a device structure assumed in this example. Operations are performed by two qubits in two lines of a column A and a column B. As already mentioned, quantum bits are shuttled from left to right in the order of numbers 0 to 6 (numbers 0 to 6 laterally illustrated in FIG. 16B) longitudinally illustrated in the device of FIG. 4. The processing of the H gate follows the flow of the measurement of FIG. 2E.

FIG. 16C depicts a circuit model command for physical quantum bits. When the device of FIG. 16B is assumed, processing performed for physical quantum bits is depicted along the time index in FIG. 16C. Quantum bits shuttled in columns A are represented by Q₁, Q₃, Q₅, Q₇, and Q₉, and quantum bits shuttled in columns B are represented by Q₂, Q₄, Q₆, Q₈, and Q₁₀. The measurement results are used as depicted by dotted lines in FIG. 16C.

FIG. 16D summarizes a measurement physical quantity necessary for circuit execution, a measurement result name, and the rotation angle φⱼ of the measurement basis B(φⱼ) programmed in an auxiliary storage unit (08004). For quantum bits in the columns A, Pauli operations X and Z with a time index 10 are performed using measurement values s1, s2, s3, and s4 of physical quantities X, Y, Y, and Y measured with time indexes 6, 7, 8, and 9. In this example, with respect to the measurement of Z, X, and Z depicted in the section of the physical quantity, the rotation angles of the XY single qubit gate section are 0, π/2, none (no operation). Quantum bits in the columns B are not measured, but the physical quantity indicates Z.

In a gate U of FIG. 16C, the operation of U_{M}(φⱼ) of (Equation 5) determined according to FIG. 16D is performed. By performing processing depending on the measurement result using the measurement result si in the final stage before the Z measurement is performed, a desired operation depicted in FIG. 16A can be performed.

In FIG. 16D, the Z measurement results s1, s2, s3, and s4 become classical information and have a value of si=±1. Each is information of one bit, and the four measurement results of s1 to s4 have four bits. Two-bit information of the power numbers (s2+s3) and (s1+s3+s4) of the Pauli operators Z and X are obtained from these four bits, and s5 is finally obtained. The added power numbers are integer values, but the amount of information can be one bit because only an even or an odd is important for the power number due to Z²=I. Which measurement result is used for the later operation is indicated by the dotted lines in FIG. 16C. The same applies to FIG. 17A to FIG. 21D below.

### (Example 2-2) Quantum Computation Processing Including S Gate

FIG. 17A depicts a quantum circuit assumed in this example. A case of performing an S gate and Z measurement depicted in FIG. 17A for logical qubits is assumed.

The device structure assumed in this example is similar to that in FIG. 16B. In addition, the circuit model command for physical quantum bits is similar to that in FIG. 16C when the operation according to a desired quantum operation is generalized to U. The processing of the S gate follows the flow of the measurement of FIG. 2F.

FIG. 17B summarizes a measurement physical quantity necessary for circuit execution, a measurement result name, and the rotation angle φⱼ of the measurement basis programmed in the auxiliary storage unit (08004). In the gate U, the operation of U_{M}(φⱼ) of (Equation 5) determined according to FIG. 17B is performed. By performing processing depending on the measurement result using the measurement result in the final stage before the Z measurement is performed, a desired operation depicted in FIG. 17A can be performed.

### (Example 2-3) Operation Including I Gate

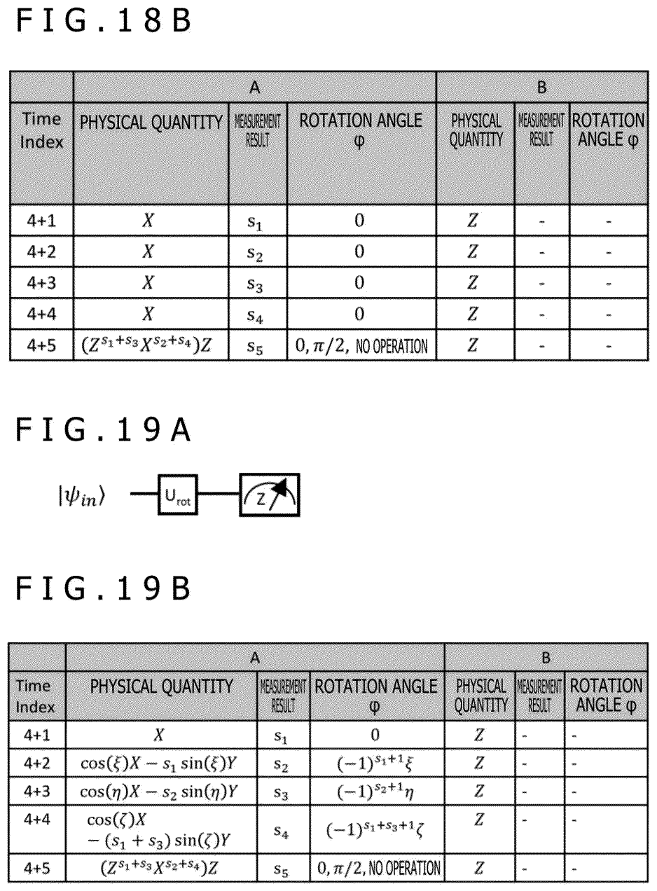

FIG. 18A depicts a quantum circuit assumed in this example. Quantum computation processing including an I gate and Z measurement as depicted in FIG. 18A is performed for logical qubits.

The device structure assumed in this example is similar to that in FIG. 16B. In addition, the circuit model command for physical quantum bits is similar to that in FIG. 16C when the operation according to a desired quantum operation is generalized to U.

FIG. 18B summarizes a measurement physical quantity necessary for circuit execution, a measurement result name, and the rotation angle φⱼ of the measurement basis programmed in the auxiliary storage unit (08004). In the gate U, the operation of U_{M}(φⱼ) of (Equation 5) determined according to FIG. 18B is performed. By performing processing depending on the measurement result using the measurement result in the final stage before the Z measurement is performed, a desired operation depicted in FIG. 18A can be performed.

Note that the operation I for logical qubits is given by the matrix of (Equation 18).

$$\begin{matrix}[ Math . 18 ] & \\ [ \begin{matrix}1 & 0 \\ 0 & 1\end{matrix} ] & ( Equation 18 )\end{matrix}$$

### (Example 2-4) Quantum Computation Processing Including Urot Gate

FIG. 19A depicts a quantum circuit of an optional single qubit Uᵣₒₜ gate of (Equation 9) and Z measurement to be performed for logical qubits in this example.

The device structure assumed in this example is similar to that in FIG. 16B. In addition, the circuit model command for physical quantum bits is similar to that in FIG. 16C when the operation according to a desired quantum operation is generalized to U.

FIG. 19B summarizes a measurement physical quantity necessary for circuit execution, a measurement result name, and the rotation angle φⱼ of the measurement basis programmed in the auxiliary storage unit (08004). In the gate U, the operation of U_{M}(φⱼ) of (Equation 5) determined according to FIG. 19B is performed. Note that, at this time, the rotation calculation φ of each U_{M}(φⱼ) is determined depending on the measurement results s1, s2, and s3. Further, by performing processing depending on the measurement result using the measurement result in the final stage before the Z measurement is performed, a desired operation depicted in FIG. 19A can be performed.

The example 2-1 to example 2-4 aim at performing different gate operations for the logical qubits, and in these examples, different quantum operations are performed for the physical quantum bits. Note that the device structures assumed above may be common. However, the operation for the desired logical qubits and the operation for the desired physical quantum bits are different from each other. According to the above tables, the different operations are executed as the U gate in FIG. 16C to be programmed.

### (Example 2-5) Quantum Computation Processing Including CNOT Gate

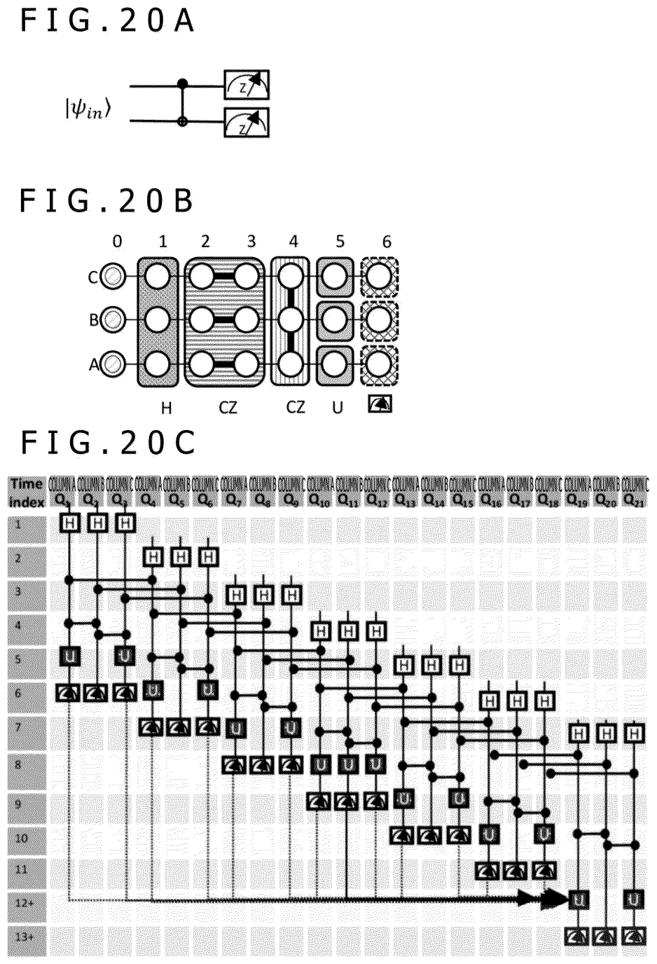

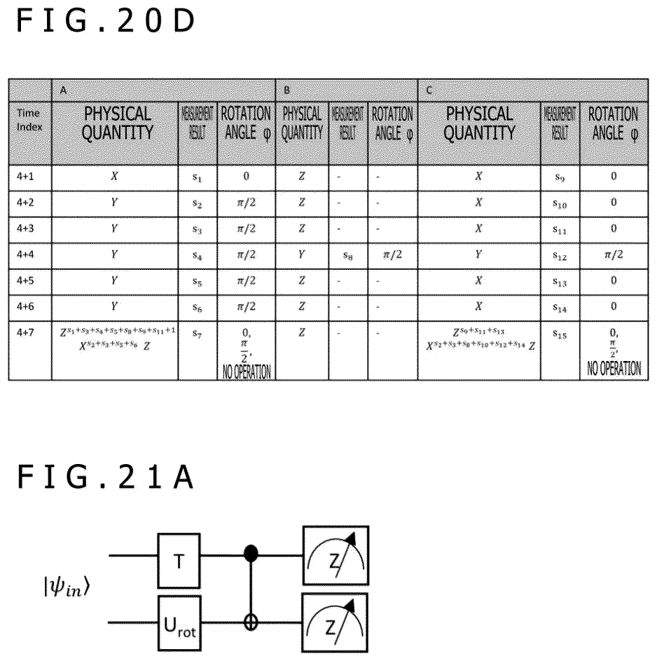

FIG. 20A to FIG. 20D are diagrams for depicting a device operation for implementing quantum computation processing including a CNOT gate by the one way quantum computation and the shuttling proposed in the embodiment.

FIG. 20A is a diagram for illustrating the quantum computation processing to be executed, with a circuit model command for logical qubits.

FIG. 20B is a schematic diagram of a device structure for implementing processing of the circuit model of FIG. 20A in the embodiment. Unlike the example in FIG. 16B, an operation is performed by three qubits in three lines of a column A, a column B, and a column C.

FIG. 20C depicts a circuit model command for physical quantum bits upon implementing processing of the circuit model of FIG. 20A in the embodiment. Quantum bits shuttled in columns A are represented by Q₁, Q₄, Q₇, Q₁₀, Q₁₃, Q₁₆, and Q₁₉, quantum bits shuttled in columns B are represented by Q₂, Q₅, Q₈, Q₁₁, Q₁₄, Q₁₇, and Q₂₀, and quantum bits shuttled in columns C are represented by Q₃, Q₆, Q₉, Q₁₂, Q₁₅, Q₁₈, and Q₂₁. The measurement results are used as depicted by dotted lines in FIG. 16C.

FIG. 20D is a table diagram for depicting a measurement axis command programmed to implement processing of the circuit model of FIG. 20A in the embodiment. A case of performing a CNOT gate and Z measurement depicted in FIG. 20A for logical qubits is assumed. At this time, when assuming the device of FIG. 20B, it is necessary to perform the processing of FIG. 20C for physical quantum bits.

FIG. 20D summarizes a measurement physical quantity necessary for circuit execution, a measurement result name, and the rotation angle φⱼ of the measurement basis programmed in the auxiliary storage unit (08004). In the gate U of FIG. 20C, the operation of U_{M}(φⱼ) of (Equation 5) is performed by the measurement axis command determined according to FIG. 20D. By performing processing depending on the measurement result using the measurement result in the final stage before the Z measurement is performed, a desired operation depicted in FIG. 20A can be performed.

### (Example 2-6) Quantum Computation Processing Including T, U, and CNOT Gates

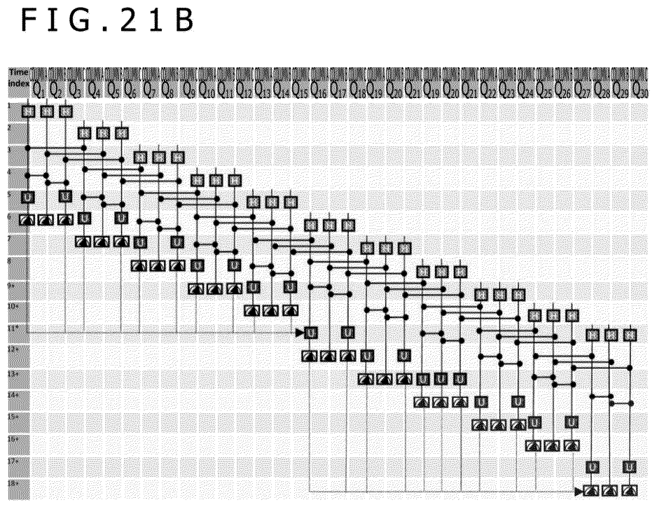

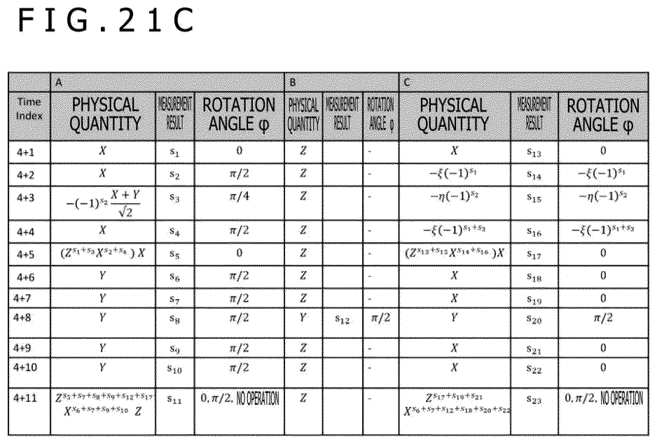

FIG. 21A to FIG. 21C depict examples of a device operation for implementing quantum computation processing including a T gate, a U gate as optional single qubit rotation, and a CNOT gate by the one way quantum computation and the shuttling proposed in the embodiment.

FIG. 21A is a diagram for depicting the quantum computation processing to be executed, with a circuit model for logical qubits. The schematic diagram of the device for implementing the processing of the circuit model command depicted in FIG. 21A in the present embodiment may be similar to that in FIG. 20B by generalizing U.

FIG. 21B depicts a measurement axis command programmed to implement the processing of the circuit model command of FIG. 21A in the present embodiment. The meanings of the reference signs in FIG. 21B are the same as those in FIG. 20C.

Quantum computation processing including the Uᵣₒₜ of (Equation 9) and the CNOT gate depicted in FIG. 21A is performed for logical qubits. At this time, when assuming the device of FIG. 20B, it is necessary to perform the processing of FIG. 21B for physical quantum bits.

FIG. 21C summarizes a measurement physical quantity necessary for circuit execution, a measurement result name, and the rotation angle φⱼ of the measurement basis programmed in the auxiliary storage unit (08004). In the gate U of FIG. 21B, the operation of U_{M}(φⱼ) of (Equation 5) determined according to FIG. 21C is performed. By performing processing depending on the measurement result using the measurement result after the execution of the T gate and the Uᵣₒₜ gate and in the final stage before the Z measurement is performed, a desired operation depicted in FIG. 21A can be performed.

Note that the operation T for logical qubits is given by the matrix of (Equation 19).

$$\begin{matrix}[ Math . 19 ] & \\ [ \begin{matrix}1 & 0 \\ 0 & \frac{1 + i}{\sqrt{2}}\end{matrix} ] & ( Equation 19 )\end{matrix}$$

Other general quantum operation processing can be implemented by combining the operations described in FIG. 16 to FIG. 21C. Common codes that perform shuttling can be used for the control programs of the quantum devices, and most of the control codes do not change. Only the real number sequence that determines the measurement axis can be rewritten for each program to be executed.

As described above, in order to implement quantum computation, a mechanism for implementing at least three kinds of operations, i.e., a single qubit gate operation, a two qubit gate operation, and quantum measurement, for all the quantum bits is necessary. If such multifunctional physical quantum bits are to be formed, the density of control wirings increases, and large-scale integration becomes difficult. In addition, a problem of a decrease in operation accuracy due to crosstalk and the like arise, for example.

According to the above embodiments, in the quantum dot array where a plurality of quantum dots are present, by assigning processing necessary for quantum computation to each portion in the quantum dot array, it is possible to simplify the structure and reduce the density of wirings, and it is thus expected to improve operation accuracy.

Further, by the shuttling operation for moving electrons without changing the electron spin state, the movement path by shuttling is fixed through the functions necessary for quantum computation assigned to each portion in the quantum dot array, and the complexity of path selection is eliminated. In particular, by executing generation up to disposal of quantum bits by shuttling in one direction, pipeline processing for a plurality of quantum bits can be performed by simple shuttling control.

According to the above embodiments, a qubit array with a high degree of integration can be implemented. Therefore, energy consumption can be reduced, the amount of carbon emissions can be reduced, global warming can be prevented, and it is possible to contribute to realization of a sustainable society.

1. A qubit array having at least two quantum dot lines extending in a first direction, the array comprising:
a single qubit gate section for performing a single qubit gate operation for a plurality of quantum bits on the quantum dot lines;
an entanglement state generation section that includes a longitudinal two qubit gate section for performing a two qubit gate operation in the first direction for the plurality of quantum bits and a lateral two qubit gate section for performing a two qubit gate operation in a second direction for the plurality of quantum bits, the second direction being different from the first direction;
an XY single qubit gate section for performing a rotation operation around a preset arbitrary axis for the plurality of quantum bits according to a program given from outside;
a Z measurement section for performing a measurement operation for the plurality of quantum bits; and
a control section for performing a shuttling operation for the plurality of quantum bits in the first direction.

2. The qubit array according to claim 1,
wherein the control section shuttles the quantum bits in the order of the single qubit gate section, the entanglement state generation section, the XY single qubit gate section, and the Z measurement section.

3. The qubit array according to claim 2,
wherein the control section shuttles the quantum bits in the order of the lateral two qubit gate section and the longitudinal two qubit gate section in the entanglement state generation section.

4. The qubit array according to claim 2,
wherein the control section shuttles the quantum bits in the order of the longitudinal two qubit gate section and the lateral two qubit gate section in the entanglement state generation section.

5. The qubit array according to claim 1,
wherein the single qubit gate section includes an H gate or an Ry(π/2) gate.

6. The qubit array according to claim 1,
wherein the entanglement state generation section includes a CZ gate.

7. The qubit array according to claim 1,
wherein the longitudinal two qubit gate section includes a CZ gate, a CZ gate equivalent circuit having a combination of a CROT gate and a single qubit gate, or a CZ gate equivalent circuit having a combination of a √SWAP^{†} gate and a single qubit gate.

8. The qubit array according to claim 1,
wherein the lateral two qubit gate section includes a CZ gate, a CZ gate equivalent circuit having a combination of a CROT gate and a single qubit gate, or a CZ gate equivalent circuit having a combination of a √SWAP^{†} gate and a single qubit gate.

9. The qubit array according to claim 1, comprising:
a physical quantum bit generation section for supplying the quantum bits to the single qubit gate section,
wherein the quantum bits are disposed of after the measurement operation by the Z measurement section.

10. The qubit array according to claim 9,
wherein shuttling of the quantum bits starts from the physical quantum bit generation section and ends at the Z measurement section, and the plurality of quantum bits on a path of the shuttling are subjected to pipeline processing.

11. A quantum computer including an input unit, an output unit, a storage unit, a processing unit, and a quantum operation unit using the qubit array according to claim 1,
wherein the input unit receives a quantum algorithm, and
the processing unit generates a control command for controlling the qubit array according to the quantum algorithm.

12. The quantum computer according to claim 11,
wherein the processing unit fixes, when generating the control command, a command other than a command given to the XY single qubit gate section.

13. The quantum computer according to claim 11,
wherein the processing unit converts the quantum algorithm based on a gate model into an operation based on a basic quantum gate, converts the basic quantum gate into single qubit measurement according to a rule of measurement-based quantum computation, and generates the control command according to the single qubit measurement.

14. A quantum information processing method performed by a qubit array having at least two quantum dot lines extending in a first direction,
the qubit array including
a single qubit gate section for performing a single qubit gate operation for a plurality of quantum bits on the quantum dot lines,
an entanglement state generation section that includes a longitudinal two qubit gate section for performing a two qubit gate operation in the first direction for the plurality of quantum bits and a lateral two qubit gate section for performing a two qubit gate operation in a second direction for the plurality of quantum bits, the second direction being different from the first direction,
an XY single qubit gate section for performing a rotation operation around a preset arbitrary axis for the plurality of quantum bits according to a program given from outside,
a Z measurement section for performing a measurement operation for the plurality of quantum bits, and
a control section for moving the plurality of quantum bits in the first direction,
the method comprising:
a first step of performing a single qubit gate operation for a first quantum bit and a second quantum bit in the single qubit gate section;
a second step of moving the first quantum bit and the second quantum bit to the entanglement state generation section by the control section;
a third step of entangling the first quantum bit and the second quantum bit in the entanglement state generation section;
a fourth step of moving the first quantum bit and the second quantum bit to the XY single qubit gate section by the control section;
a fifth step of performing the rotation operation for at least one of the first quantum bit and the second quantum bit in the XY single qubit gate section;
a sixth step of moving the first quantum bit and the second quantum bit to the Z measurement section by the control section; and
a seventh step of performing the measurement operation for at least one of the first quantum bit and the second quantum bit in the Z measurement section.

15. The quantum information processing method according to claim 14,
wherein, at a timing when at least one of the first to seventh steps is executed for the first quantum bit and the second quantum bit,
at least one of the first to seventh steps is executed for a third quantum bit and a fourth quantum bit.
